(19) United States
(12) Patent Application Publication
(10) Pub. No.: US 2018/0085853 A1
(43) Pub. Date: Mar. 29, 2018

(54) TREATMENT APPARATUS, COMPONENT FEEDER, AND TREATMENT METHOD

(71) Applicant: MURATA MANUFACTURING CO., LTD., Kyoto-fu (JP)

(72) Inventors: Reiichi MATSUBA, Nagaokakyo-shi (JP); Sakae KOTO, Nagaokakyo-shi (JP); Daisuke KATAYAMA, Nagaokakyo-shi (JP); Masato ABE, Nagaokakyo-shi (JP); Keita MOTOYOSHI, Nagaokakyo-shi (JP); Hideki MURAMATSU, Nagaokakyo-shi (JP)

(73) Assignee: MURATA MANUFACTURING CO., LTD., Kyoto-fu (JP)

(21) Appl. No.: 15/713,131

(22) Filed: Sep. 22, 2017

(30) Foreign Application Priority Data
Sep. 23, 2016 (JP) 2016-185803
May 31, 2017 (JP) 2017-107649

(51) Int. Cl. B23K 26/08; H01L 21/68

(52) U.S. Cl. CPC B23K 26/08; H01L 21/68

(57) ABSTRACT

A treatment apparatus includes a feeding device and a laser device. The feeding device includes a feeding rotor and a motor. The feeding rotor is rotatably supported. In the outer peripheral surface of the feeding rotor, a support portion extending in a circumferential direction of the feeding rotor is formed, and holding grooves are formed in the support portion at equal angular intervals. The laser device treats the element body fed to a treatment position. A control device controls the motor so as to stop the feeding rotor at every predetermined angle (an angle at which the holding groove is formed) and to feed the element body to a treatment position. Then, the control device controls the laser device so as to treat a surface of the element body.

### CROSS REFERENCE TO RELATED APPLICATIONS

This application claims benefit of priority to Japanese Patent Application 2016-185803 filed Sep. 23, 2016, and Japanese Patent Application 2017-107649 filed May 31, 2017, the entire content of which is incorporated herein by reference.

### TECHNICAL FIELD

The present disclosure relates to a treatment apparatus for performing treatment related to manufacture of electronic components and a treatment method. The present disclosure also relates to a component feeder constituting the treatment apparatus.

### BACKGROUND

Conventionally, an electronic component to be mounted on a wiring board is formed through various treatment processes. For example, an external terminal of an electronic component is formed using a method of applying plating to a primary electrode formed by coating an element body with conductive paste, or a method of applying electroless plating to an end face of an internal electrode contained in the element body while the end face is exposed (e.g., refer to Japanese Patent Application Laid-Open No. 2004-40084), for example.

Recently, downsizing and improvement in performance of an electronic apparatus, such as a cellular phone, have progressed, so that downsizing of electronic components mounted in that kind of electronic apparatus is also increasingly required. Then, high treatment capacity is required in a manufacturing process of a small-sized electronic component. Unfortunately, it is difficult to improve treatment capacity by using the above various methods of forming an external terminal, for example.

The present disclosure is made to solve the above problem, and an object thereof is to provide a treatment apparatus, a component feeder, and a treatment method, capable of improving capacity in treatment of an element body constituting an electronic component.

### SUMMARY

A treatment apparatus to solve the above problem, treats an element body constituting an electronic component, the treatment apparatus including: a feeding system that includes a feeding rotor that is rotatably supported, and a drive unit that rotationally drives the feeding rotor, wherein the feeding rotor has a plurality of holding grooves to hold the element bodies, and the plurality of holding grooves are disposed at equal angular intervals in an edge portion of the feeding rotor along a circumferential direction of the feeding rotor, and the feeding system feeds the element bodies held in the corresponding holding grooves; a supply system that supplies the element bodies to the corresponding holding grooves; a treatment device that treats each of the element bodies at a treatment position; and an control system that controls the feeding system so as to feed each of the element bodies to the treatment position by rotationally driving the feeding rotor, and that controls the treatment device so as to treat each of the element bodies being fed.

According to this structure, chips are fed by the circular feeding rotor so that each of their element bodies is treated at a predetermined treatment position. As a result, treatment can be efficiently performed, or capacity in the treatment can be improved, as compared with a case where chips disposed on a table are treated, for example. In addition, the feeding rotor is rotationally driven to feed element bodies, so that the plurality of element bodies can be treated without changing position of the treatment device, thereby enabling improvement in treatment capacity.

In the above treatment apparatus, it is preferable that each of the holding grooves is formed so as to hold the element body when a part of two adjacent faces of the element body is in contact with the holding groove while allowing all two faces thereof parallel to the corresponding faces in contact with each of the holding grooves to project from the corresponding one of the holding grooves, and the element body is a rectangular parallelepiped shape and has two side faces which are each parallel to the corresponding one of the two faces in contact with each of the holding grooves, and has two end faces orthogonal to the two side faces and to the two faces in contact with each of the holding grooves, and also the control system controls the treatment device so as to treat one of the two side faces in non-contact with each of the holding grooves and the two end faces. The shape of a “rectangular parallelepiped” includes a shape of a rectangular parallelepiped with rounded corners or rounded ridge lines, for example.

According to this structure, adjacent two side faces of the element body are brought into contact with the holding groove of the feeding rotor, so that the element body can be stably held. Then, in the element body held in the holding groove, at least one of two side faces in non-contact with the holding groove and two end faces can be treated.

In the above treatment apparatus, it is preferable that the control system controls the feeding system so as to stop the feeding rotor at every angle at which each of the holding grooves is formed, and controls the treatment device so as to treat the element body stopped at the treatment position.

According to this structure, the feeding rotor is stopped at every angle at which the holding groove is formed, so that the element body can be reliably stopped at the treatment position. Then, the element body stopped at the treatment position can be accurately treated.

In the above treatment apparatus, it is preferable that the feeding rotor is supported to be able to vertically rotate by having a rotating shaft supported horizontally, and is provided on its outer peripheral surface with a support portion extending along its circumferential direction, and that each of the holding grooves is provided in an outer peripheral surface of the support portion, and is formed so as to extend in a thickness direction of the feeding rotor, and that the support portion is formed such that both end faces of the element body held in each of the holding grooves project from the support portion in a direction parallel to the rotating shaft of the feeding rotor.

According to this structure, the feeding rotor vertically (longitudinally) rotates by using the rotating shaft supported horizontally. The element body is held in the support portion of the feeding rotor that vertically rotates as described above such that its end faces project in a direction parallel to the rotating shaft. Thus, the end faces of the element body can be easily treated. The element body is held such that its end faces project from the support portion, and thus the support portion or the feeding rotor can be prevented from being affected by treatment in the treatment device.

In the above treatment apparatus, it is preferable that the feeding rotor is supported to be able to horizontally rotate by having a rotating shaft supported vertically, and is provided on its top face with an annular support portion extending along a circumferential direction, and that the holding groove is provided in a top face of the support portion, and is formed so as to extend in a radial direction of the feeding rotor, and that the support portion is formed such that one of both end faces of the element body held in the holding groove projects radially inward from the support portion, and the other of both the end faces projects radially outward from the support portion.

According to this structure, the feeding rotor horizontally (laterally) rotates by using the rotating shaft supported vertically. The element body is held in the support portion of the feeding rotor that horizontally rotates as described above, so that the element body can be fed in a stable state. The element body is held such that its end faces project from the support portion, and thus the support portion or the feeding rotor can be prevented from being affected by treatment in the treatment device.

It is preferable that the above treatment apparatus includes a photographing system that photographs the element body and the feeding rotor at a predetermined recognition position, and that the control system grasps a position of the element body on the basis of a photographed result of the photographing system, and corrects a position at which the treatment device treats the element body, in accordance with the grasped position of the element body.

According to this structure, when the element body is fed to the feeding rotor from the supply system, the element body may be displaced in position. For that, the photographing system photographs the element body held by the feeding rotor to grasp a position of the element body, and a treatment position is corrected in accordance with the grasped position, thereby enabling treatment with high accuracy.

In the above treatment apparatus, it is preferable that the electronic component includes the element body being a ceramic element, and an external electrode formed on a surface of the element body, and that the treatment device is a laser treatment device that locally heats a surface of the ceramic element to reduce resistance in a part of the ceramic element.

According to this structure, the element body being a ceramic element is irradiated with a laser beam, so that a surface of the minute element body can be locally and accurately heated. When the ceramic element is locally heated as described above to reduce resistance in its local portion, an external electrode can be formed by applying plating to the local portion.

In the above treatment apparatus, it is preferable that the treatment device includes a first treatment device configured to treat one of the two side faces, a second treatment device configured to treat the other of the two side faces, and a third treatment device and a fourth treatment device, configured to treat the corresponding two end faces.

According to this structure, end faces and side faces of the element body held in the feeding rotor can be treated. Then, the element body is held such that its two side faces in non-contact with the holding groove project from the holding groove, and thus the feeding rotor can be prevented from being affected by treatment in the treatment device.

In the above treatment apparatus, it is preferable that the control system controls one of either the first treatment device or the second treatment device, the third treatment device, and the fourth treatment device, so as to treat one side face and two end faces of the element body.

According to this structure, one side face and two end faces of the element body can be treated. When one of two side faces in non-contact with the holding groove in the element body held in the holding groove is a face to be treated, the first treatment device or the second treatment device is controlled for treatment depending on a state (posture) of the element body held in the holding groove, and thus a side face of the element body being fed can be treated without being affected by a state of the element body.

In the above treatment apparatus, it is preferable that the control system controls the first treatment device or the second treatment device on the basis of a photographed result of the photographing system so as to treat a side face corresponding to the controlled treatment device.

According to this structure, one of two side faces of the element body, in non-contact with the holding groove, to be treated, is grasped, and the first treatment device or the second treatment device corresponding to the face to be treated is controlled so as to treat the face, so that the side face of the element body being fed can be treated without being affected by a state of the element body.

In the above treatment apparatus, it is preferable that treatment positions at which the corresponding first to fourth treatment devices treat the element body are set along a rotation direction of the feeding rotor.

According to this structure, the element body is held in the holding groove while its side faces are in contact with the holding groove. For example, when a surface of the element body is treated, the element body may be displaced in position. The element body is displaced in position along the side faces held in the holding groove. However, the end faces of the element body are not displaced in position as viewed from a direction along the side faces of the element body. Thus, treating the end faces after the side faces are treated enables the respective faces to be accurately treated.

In the above treatment apparatus, it is preferable that the element body includes a shank, a first flange connected to one end of the shank, and a second flange connected to the other end of the shank, each of the flanges has a first side face, a second side face provided with one end connected to one end of the first side face, a third side face provided with one end connected to the other end of the first side face, a fourth side face connected to both of the other end of the second side face and the other end of the third side face, and an end face connected to all of the first side face, the second side face, the third side face, and the fourth side face, and that the holding groove has a first holding face to be in contact with the first side face of each of the flanges, and a second holding face to be in contact with the second side face of each of the flanges, and that the control system controls the treatment device so as to treat a face in non-contact with the first holding face and the second holding face, in the faces constituting at least one of the two flanges.

According to this structure, the first side face of each of the flanges is brought into contact with the first holding face of the holding groove, and the second side face of each of the flanges is brought into contact with the second holding face of the holding groove, so that the feeding rotor can stably hold the element body in the holding groove. Then, in at least one of the flanges of the element body held in the holding groove, the treatment device can treat a face in non-contact with the first holding face and the second holding face of the holding groove, or at least one of the third side face, the fourth side face, and the end face.

In the above treatment apparatus, it is preferable that the feeding system is configured to suction at least one of the respective flanges of the element body held in each of the holding grooves.

According to this structure, at least one of the respective flanges of the element body is suctioned onto a face constituting the holding groove, so that the element body can be held in the holding groove.

In the above treatment apparatus, it is preferable that the feeding rotor has a protrusion protruding from the first holding face, the protrusion being positioned between the first flange and the second flange of the element body held in each of the holding grooves.

According to this structure, when a direction in which the first flange, the shank, and the second flange align is indicated as an axial direction of the element body, the protrusion can prevent the element body held in the holding groove from being displaced in the axial direction. That is, the element body held in the holding groove can be prevented from being displaced in position.

In the above treatment apparatus, it is preferable that the feeding rotor has a protrusion protruding from the first holding face, the protrusion being positioned between the first flange and the second flange of the element body held in each of the holding grooves, and that the protrusion includes a suction port through which the shank of the element body held in each of the holding grooves is suctioned.

According to this structure, not only at least one of the respective flanges but also the shank can be suctioned in the element body held in the holding groove. This enables a holding position of the element body held in the holding groove to be more accurately prevented from being displaced.

In the above treatment apparatus, it is preferable that each of the holding grooves is formed in a shape suitable for each of the flanges of the element body held in each of the holding grooves.

According to this structure, the holding groove is formed in a shape suitable for the flanges constituting the element body, so that the element body can be easily held in the holding groove.

In the above treatment apparatus, it is preferable that each of the flanges of the element body is formed such that the first side face is longer than the second side face, and that each of the holding grooves is formed such that the first holding face is longer than the second holding face.

According to this structure, it is possible to increase a contact area between the first side face of the flange in contact with the first holding face, and the first holding face, as much as possible. This enables stability when the element body is held in the holding groove to be further improved.

A component feeder to solve the above problem feeds the element body constituting an electronic component, the element body including a shank, a first flange connected to one end of the shank, and a second flange connected to the other end of the shank, each of the flanges having a first side face, a second side face provided with one end connected to one end of the first side face, a third side face provided with one end connected to the other end of the first side face, a fourth side face connected to both of the other end of the second side face and the other end of the third side face, and an end face connected to all of the first side face, the second side face, the third side face, and the fourth side face, the component feeder including: a feeding system that includes a feeding rotor that is rotatably supported, a plurality of holding grooves each of which is disposed in an edge portion of the feeding rotor at equal angular intervals along a circumferential direction of the feeding rotor to hold the element body, and a drive unit that rotationally drives the feeding rotor, and that feeds the element body held in each of the holding grooves; and a supply system that supplies the element body to each of the holding grooves, each of the holding grooves having a first holding face to be brought into contact with the first side face of each of the flanges, and a second holding face to be brought into contact with the second side face of each of the flanges, and the feeding system being configured to suction at least one of the respective flanges of the element body held in each of the holding grooves.

According to this structure, a feeding direction of the element body to which predetermined treatment is applied by the treatment device is to be a rotation direction of the feeding rotor. As a result, position accuracy of the element body held in the holding groove when a rotation angle of the feeding rotor is controlled in the feeding system with the structure described above can be improved as compared with position accuracy when the element body fed along a linear direction is stopped. Thus, when treatment is applied to the element body held in the holding groove of the feeding rotor in the component feeder with the structure described above, capacity of the treatment can be improved.

A treatment method to solve the above problem is used to treat a surface of the element body constituting an electronic component, the treatment method including the steps of: holding the element body in each of a plurality of holding grooves that is disposed in an edge portion of a feeding rotor being rotatably supported, at equal angular intervals along a circumferential direction of the feeding rotor; rotationally driving the feeding rotor to feed the element body to a treatment position set in a rotation direction of the feeding rotor; and treating a surface of the element body at the treatment position.

According to this structure, the element bodies are fed by the feeding rotor so that each of the element bodies is treated at a predetermined treatment position. As a result, treatment can be efficiently performed, or capacity in the treatment can be improved, as compared with a case where the element bodies disposed on a table are treated, for example. In addition, feeding the element body by rotationally driving the feeding rotor enables a plurality of the element bodies to be treated, so that treatment capacity can be improved.

According to the treatment apparatus, the component feeder, and the treatment method, of the present disclosure, capacity of treatment of the element body constituting an electronic component can be improved.

### BRIEF DESCRIPTION OF THE DRAWINGS

FIG. 1 is a perspective view illustrating an outline of a treatment apparatus of a first embodiment.

FIG. 2A is a perspective view illustrating a disk portion of the first embodiment, and FIG. 2B is a perspective view illustrating a periphery of a holding groove.

FIG. 3A is a side view illustrating an electronic component, and FIG. 3B is a perspective view illustrating an element body.

FIG. 4 is a schematic view illustrating delivery of an electronic component.

FIGS. 5A to 5C each are enlarged views illustrating a state of a disk portion and an electronic component.

FIG. 6A is a partially exploded perspective view of a disk portion, and FIG. 6B is a sectional view of the disk portion.

FIG. 7 is a schematic view illustrating a position of each of various kinds of treatment of a disk portion

FIG. 8 is a block diagram illustrating a configuration of a treatment apparatus.

FIG. 9 is a flowchart illustrating a flow of treatment in a treatment apparatus.

FIGS. 10A to 10C each are perspective sectional views illustrating treatment of an electronic component.

FIGS. 11A and 11B each are schematic views illustrating a disk portion of a comparative example.

FIG. 12 is a perspective view illustrating another electronic component to be treated.

FIG. 13A is a perspective view illustrating an outline of a treatment apparatus of a second embodiment, and FIG. 13B is a perspective view illustrating a disk portion of the second embodiment.

FIG. 14 is a sectional view illustrating an outline of treatment of an electronic component held in a disk portion.

FIG. 15 is a perspective view illustrating an outline of a treatment apparatus of a third embodiment.

FIGS. 16A and 16B each are perspective views illustrating an electronic component.

FIG. 17A is a perspective view of an element body, and FIG. 17B is a sectional view of the element body.

FIG. 18 is a perspective view of a feeding rotor.

FIG. 19 is a schematic view illustrating delivery of the element body.

FIGS. 20A and 20B each are enlarged views illustrating a state of a feeding rotor and the element body.

FIG. 21 is a perspective view illustrating a part of a feeding rotor.

FIG. 22 is a partially exploded perspective view of a feeding rotor.

FIG. 23 schematically illustrates a section of a part of a feeding rotor.

FIG. 24 is a block diagram illustrating a configuration of a treatment apparatus.

FIG. 25 is a schematic view illustrating a position of each of various kinds of treatment of a feeding rotor.

FIG. 26 is a flowchart illustrating a flow of treatment in a treatment apparatus.

FIGS. 27A to 27C each are perspective sectional views illustrating treatment of the element body.

FIG. 28A is a perspective view illustrating an outline of a treatment apparatus of a fourth embodiment, and FIG. 28B is a perspective view illustrating a feeding rotor of the fourth embodiment.

FIG. 29 is a sectional view illustrating an outline of treatment of the element body held by a feeding rotor.

FIG. 30A is a perspective view illustrating a part of a feeding rotor of another embodiment, and FIG. 30B schematically illustrates a section of a part of the feeding rotor.

### DETAILED DESCRIPTION

Each aspect will be described below.

In accompanying drawings, a component may be illustrated in an enlarged manner for easy understanding. A ratio of size of a component may be different from an actual ratio thereof, or from that in another drawing.

### First Embodiment

A first embodiment will be described below.

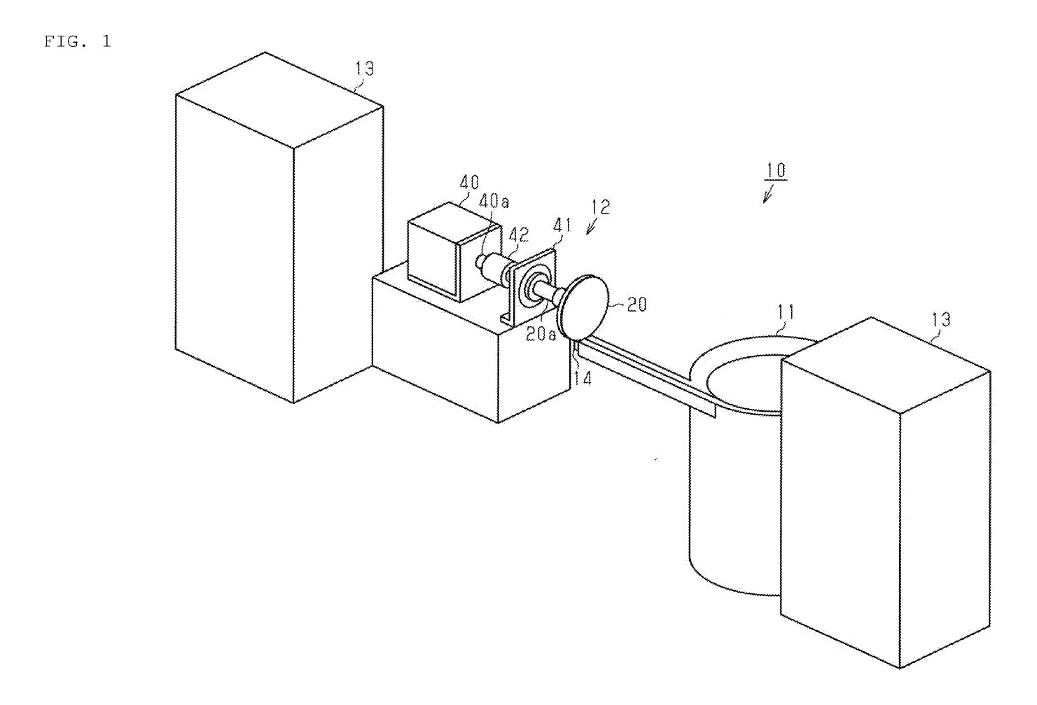

As illustrated in FIG. 1, a treatment apparatus 10 includes a part feeder 11 serving as a supply system, a feeding device 12 serving as a feeding system, and a laser device 13 serving as a treatment device. The treatment apparatus 10 has a plurality of the laser devices 13. While FIG. 1 illustrates the two laser devices 13, the number of treatment devices suitable for treatment is provided. In the description below, when laser devices are individually described, each of the laser devices is designated as a reference sign, and a reference numeral “13” is used in common description of a laser device.

The part feeder 11 sequentially supplies an object to be treated by the laser device 13 to the feeding device 12 by using vibration. The object to be treated is the element body constituting a chip-like electronic component.

The feeding device 12 feeds a supplied element body to a treatment position. In the present embodiment, the treatment apparatus 10 has a plurality of the laser devices 13, and a treatment position is set for each of the laser devices 13. The feeding device 12 sequentially feeds the element body to each treatment position, and the laser device 13 treats the element body being fed, or emits a laser beam. The treated element body is fed to an ejection position by the feeding device 12, and is ejected.

Here, the element body to be treated will be described.

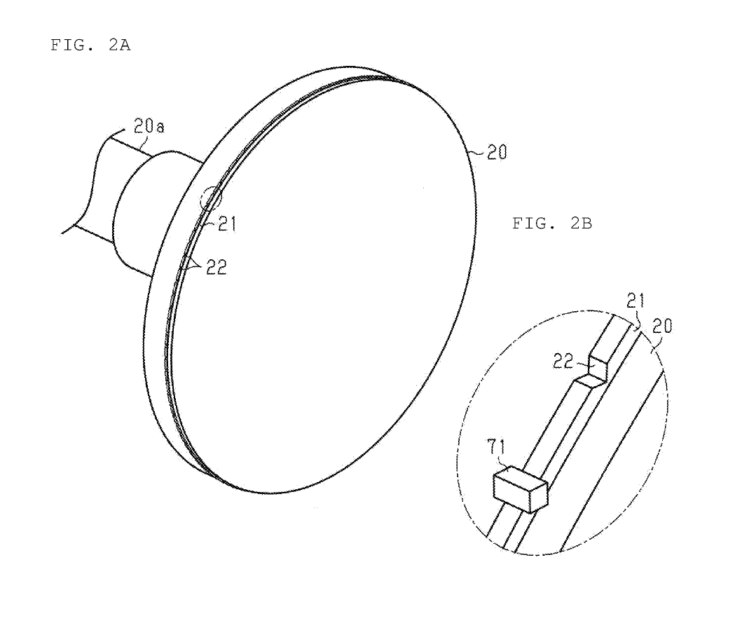

As illustrated in FIGS. 3A and 3B, an electronic component 70 of the present embodiment is formed in the shape of a rectangular parallelepiped, and has six faces. In the faces included in the electronic component 70, each of two faces to be brought into contact with a holding groove 22 described below (refer to FIG. 2B) and two faces parallel to the respective two faces to be brought into contact therewith is indicated as a side face, and each of faces orthogonal to the four side faces is indicated as an end face. That is, the electronic component 70 has the four side faces and the two end faces. In the present description, the shape of a “rectangular parallelepiped” includes a shape of a rectangular parallelepiped with rounded corners or rounded ridge lines, for example. The electronic component 70 is a capacitor, a piezoelectric component, a thermistor, or the like, for example.

The electronic component 70 is an electronic component mounted on a surface of a substrate or the like, and is a chip ferrite bead, for example. As the electronic component 70, a chip inductor or a chip capacitor may be treated, for example.

The electronic component 70 includes an element body 71 to be treated, and two external electrodes 72 and 73 formed on a surface of the element body 71. The element body 71 of the present embodiment is formed in the shape of a rectangular parallelepiped, and has four side faces 71a, 71b, 71c, and 71d, and two end faces 71e and 71f. The electronic component 70 is small in size, and has a size of 0.6 mm by 0.3 mm by 0.4 mm, for example.

The element body 71 is a sintered ceramic element, for example. The ceramic element is formed of ferrite material containing nickel (Ni) and zinc (Zn). As the ferrite material, Ni—Zn-based ferrite containing Ni and Zn as main components, and Ni—Cu—Zn-based ferrite containing Ni, Zn, and copper (Cu) as main components, are available, for example.

The element body 71 can be acquired by compressing and sintering the ferrite material described above, for example.

The external electrodes 72 and 73 are formed so as to cover the two end faces 71e and 71f of the element body 71, respectively. In addition, the external electrodes 72 and 73 are formed so as to cover a part of the side face 71a while continuously extending from the end faces 71e and 71f, respectively. The external electrodes 72 and 73 are formed by plating. As material of the external electrodes 72 and 73, Cu, aurum (Au), Ag, Pd, Ni, and Sn are available, for example. The external electrodes 72 and 73 also may be formed of multilayer plating metal.

The external electrodes 72 and 73 are formed by plating after local heat treatment is applied to the element body 71. FIG. 3B illustrates portions to which the local heat treatment is applied by hatching. The laser device 13 described above is used to apply the local heat treatment to the element body 71. As the laser device 13, a YVO4 laser device (with a wavelength of 1064 nm) is available, for example. As the treatment apparatus, an electron beam irradiation device, an image furnace, and the like are also available. The laser device 13 is preferable in that an irradiation position on the element body 71 can be quickly changed.

Local heating by the laser device 13 causes a ceramic element in a surface of the element body 71 to change in properties. The local heating causes an insulating material (ferrite) constituting the ceramic element to change in properties, so that a low resistance portion with a resistance lower than that of the insulating material is formed. It is conceivable that ferrum (Fe) or Cu contained in the ferrite is reduced by the local heating to cause the low resistance portion. The low resistance portion is adjustable in depth and size in accordance with irradiation energy of a laser beam.

The element body 71 including the low resistance portion is immersed in a plating solution so that electrolytic plating is applied to the element body 71. The low resistance portion with conductivity has an electric current density higher than that in other portions in the element body 71, so that a plating metal is deposited on a surface of the low resistance portion. The plating metal deposited as described above enables the external electrodes 72 and 73 to be formed.

Growth speed of the plating metal in a region irradiated with no laser beam is slower than growth speed of the plating metal in a region irradiated with a laser beam. This enables the plating metal to be selectively grown in a region irradiated with a laser beam without accurately controlling a plating treating time. Then, control of a plating treating time, voltage, or electric current enables an external electrode to be controlled in forming time and thickness. In addition, when an additional plating treatment is applied to an external electrode formed in a first plating treatment, an external electrode with a multilayer structure can be formed. In this case, an external electrode to be primary has been already formed, so that an additional plating treating time needs to be short.

As described above, the treatment apparatus 10 of the present embodiment sequentially feeds the element body 71 constituting the electronic component 70 described above, and the laser device 13 treats the element body 71. Feeding of the element body 71 will be described below.

As illustrated in FIG. 1, the treatment apparatus 10 includes the part feeder 11, and the feeding device 12. The part feeder 11 aligns the above element bodies 71 (refer to FIG. 3A) by using vibration, and feeds them. In the present embodiment, the part feeder 11 aligns the element bodies 71 such that the side face 71a to be treated of each of the element bodies 71 faces downward. Each of the element bodies 71 fed by the part feeder 11 is delivered to the feeding device 12 through a non-vibration portion 14 provided at a leading end of the part feeder 11.

The feeding device 12 includes a feeding rotor 20, and a motor 40 serving as a drive unit for rotationally driving the feeding rotor 20. The feeding rotor 20 has a diameter of 70 mm in size, for example. The diameter is relatively small, so that positional displacement caused by vibration of the feeding rotor 20 can be reduced even if the feeding rotor 20 is rotationally driven at high speed (e.g., 4000 rpm). The feeding rotor 20 has a rotating shaft 20a that is rotatably supported by a supporting stand 41 including a bearing. The rotating shaft 20a is coupled to an output shaft 40a of the motor 40 with a coupling 42. The coupling 42 allows misalignment between the rotating shaft 20a of the feeding rotor 20 and the output shaft 40a of the motor 40.

As illustrated in FIG. 2A, a support portion 21 extending along a circumferential direction of the feeding rotor 20 is formed in an outer peripheral surface of the feeding rotor formed in a circular shape. As illustrated in FIG. 2B, at least one holding groove 22 is formed in the support portion 21, and the element body 71 is held in the holding groove 22. The element body 71 is held in the holding groove 22 by vacuum suction.

The holding groove 22 is formed so as to extend in a direction parallel to the rotating shaft of the feeding rotor 20.

The holding groove 22 is formed in a V-shape as viewed from a direction of the rotating shaft of the feeding rotor 20 so as to hold the element body 71 to be fed at an angle. At this time, the element body 71 is held such that its side face 71a to be treated is positioned radially outside of the feeding rotor 20. In other words, the above part feeder 11 aligns the element body such that the side face 71a to be treated is positioned radially outside of feeding rotor 20. In addition, the part feeder 11 may align the element body 71 such that the side face 71a to be treated faces a constant direction.

The holding grooves 22 are formed in an edge portion of the feeding rotor 20 at equal intervals (at equal center angular intervals) in the circumferential direction. For example, the holding groove 22 is formed every three degrees. That is, 120 holding grooves 22 are formed in the feeding rotor 20. This allows 120 element bodies 71 to be treated in one turn of the feeding rotor 20.

Subsequently, delivery of the element body 71 from the part feeder 11 to the feeding rotor 20 will be described.

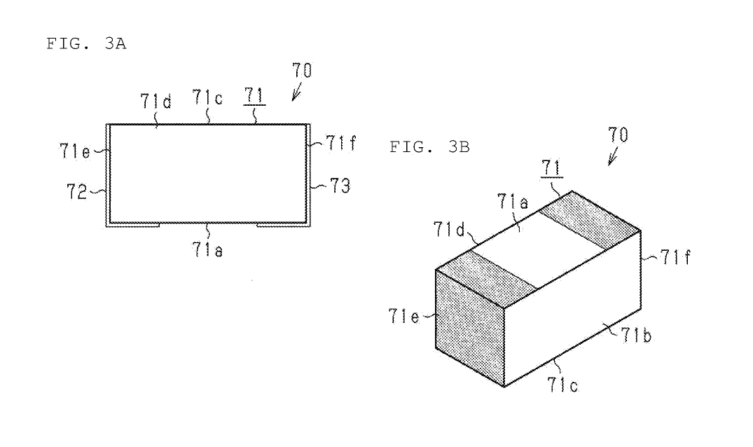

As illustrated in FIG. 4, the part feeder 11 is provided at its leading end with the non-vibration portion 14.

The non-vibration portion 14 includes a contact member 14a with which each of the element bodies 71 is brought into contact for positioning, and a separating pin 14b for separating each of the element bodies 71. The separating pin 14b is moved by a separating pin drive unit described below, in a vertical direction of FIG. 4. The contact member 14a is coupled to a vacuum pump described below. When the separating pin 14b descends, the element body 71 is suctioned by the contact member 14a. Then, the separating pin 14b rises to separate the element body 71 to be fed subsequently from the element body 71 suctioned by the contact member 14a. The element body 71 suctioned by the contact member 14a is brought into contact with the contact member 14a, and is positioned by the contact member 14a. Then, the element body 71 is held in the holding groove 22 illustrated in FIG. 2B.

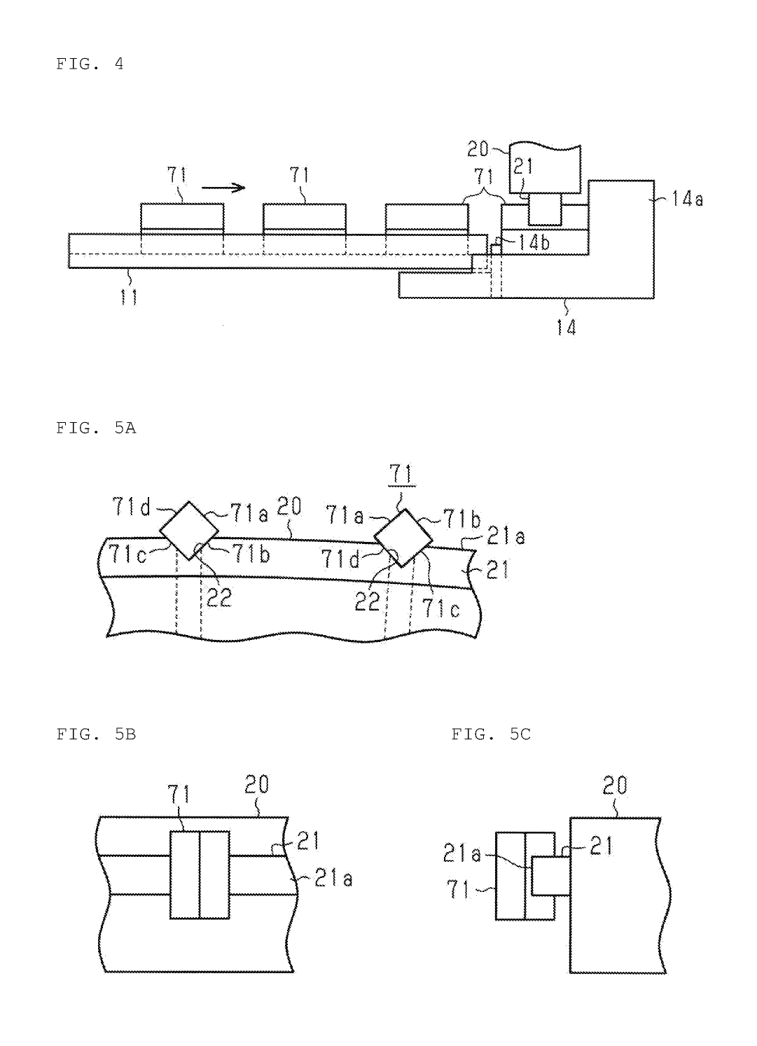

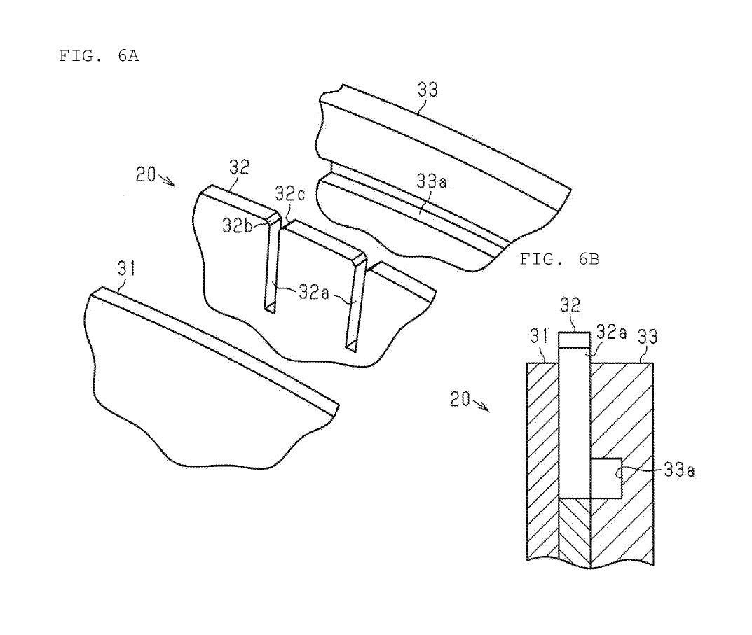

With reference to FIGS. 5A to 5C, a state of the element body 71 held in the feeding rotor 20 will be described. As illustrated in the left side of FIG. 5A, the element body 71 is held such that its two side faces 71a and 71d project radially outward (upward in FIG. 5A) from a side face (outer peripheral surface) 21a of the support portion 21. In addition, as illustrated in the right side of FIG. 5A, the element body 71 is held such that its two side faces 71a and 71b project. In other words, the holding groove 22 is formed such that a part of each of the adjacent two side faces 71b and 71c (or side faces 71c and 71d) of the element body 71 is to be in contact with the holding groove 22 and all of the two side faces 71a and 71d (or the side faces 71a and 71b) to be in non-contact therewith project from an upper end of the holding groove 22. As illustrated in FIGS. 5B and 5C, the end faces of the element body 71 project from the support portion 21 in a thickness direction (a vertical direction in FIGS. 5B and 5C, or a direction parallel to the rotating shaft) of the support portion 21. In other words, the support portion 21 holds a central portion of the element body 71 in the shape of a rectangular parallelepiped.

Subsequently, an example of structure of the feeding rotor 20 will be described.

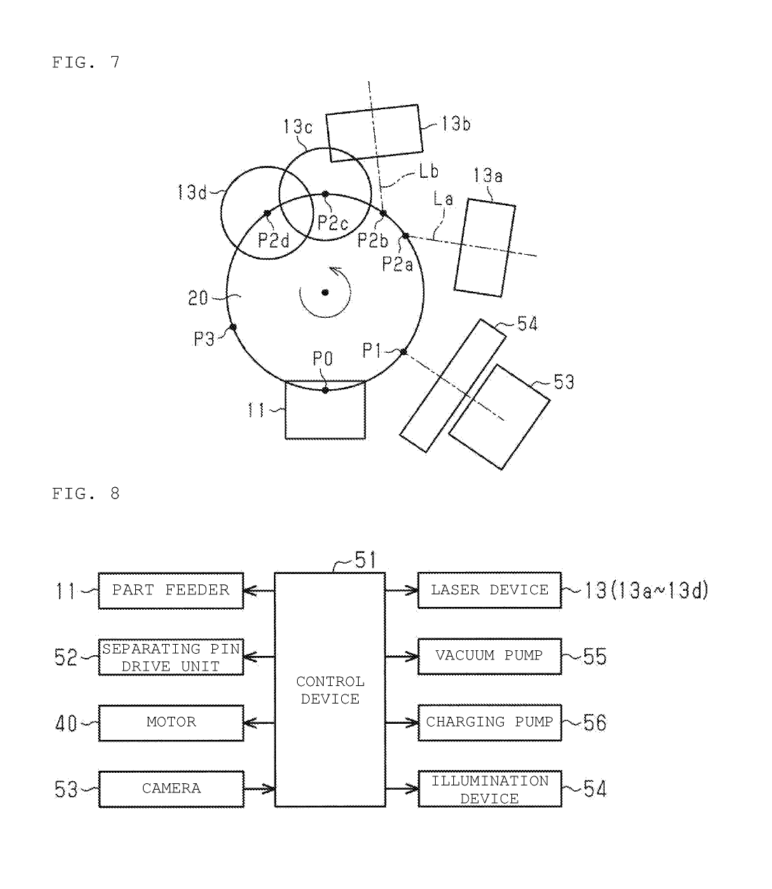

As illustrated in FIG. 6A, the feeding rotor 20 is formed of three disks 31, 32, and 33 stacked with each other in an axial direction.

The first disk 31 is formed in a plate shape. The second disk 32 is provided with a plurality of through-holes 32a extending through the second disk 32 in its thickness direction. Each of the through-holes 32a is formed at every predetermined angle (every three degrees in the present embodiment), and extends to an end of the disk 32 along its radial direction. The disk 32 includes inclined surfaces 32b and 32c inclined in a circumferential direction of the disk 32 at a radially outward end of through-hole 32a, and the inclined surfaces 32b and 32c are formed so as to form a right angle with each other. The inclined surfaces 32b and 32c constitute the holding groove 22 illustrated in FIG. 2B. In a state where the first to third disks 31 to 33 are stacked with each other, the first disk 31 and the third disk 33 are formed so as to cover a part of the through-hole 32a formed in the second disk 32 across a thickness direction of the second disk 32. As illustrated in FIG. 6B, the second disk 32 is formed larger than the first and third disks 31 and 33. The support portion 21 illustrated in FIG. 2B is formed of a projecting portion of the second disk 32.

The third disk 33 is provided with a communication groove 33a extending along its circumferential direction. As illustrated in FIG. 6B, the communication groove 33a communicates with the through-hole 32a formed in the second disk 32 in a state where the first to third disks 31 to 33 are stacked with each other. The communication groove 33a is connected to a vacuum pump 55 described below. Thus, the through-hole 32a and the communication groove 33a constitute a suction port formed at a bottom of the holding groove 22 to suction the element body 71 (refer to FIG. 2B) through the suction port. FIGS. 6A and 6B illustrate an outline of components required to form the suction port in the feeding rotor 20.

As described above, when the first to third disks 31 to 33 constitute the feeding rotor 20, the feeding rotor 20 provided with the suction port can be easily formed to reduce manufacturing costs. That is, the feeding rotor 20 includes the suction port extending along its radial direction. The suction port has a very small inner diameter (e.g., 0.25 mm) to suction the minute element body 71. It is very difficult to machine the suction port as described above with a drill, for example, so that the machining requires a long time. Thus, forming the suction port along the radial direction causes manufacturing of a feeding rotor to be very difficult, so that manufacturing costs increase.

In contrast, the feeding rotor of the present embodiment is formed such that the second disk 32 is provided with the through-hole 32a extending through the second disk 32 in its thickness direction to form the suction port extending in the radial direction of the feeding rotor by covering a part of the through-hole 32a with the first disk 31 and the third disk 33 stacked with the second disk 32. In the second disk 32, it is easy to form the through-hole 32a extending through the second disk 32 in its thickness direction while extending in its radial direction. In the third disk 33, it is also easy to form the communication groove 33a extending in its circumferential direction.

Thus, the feeding rotor 20 composed of the first to third disks 31 to 33 can be easily formed, so that costs required for manufacture are reduced.

Subsequently, an electrical configuration of a treatment apparatus will be described.

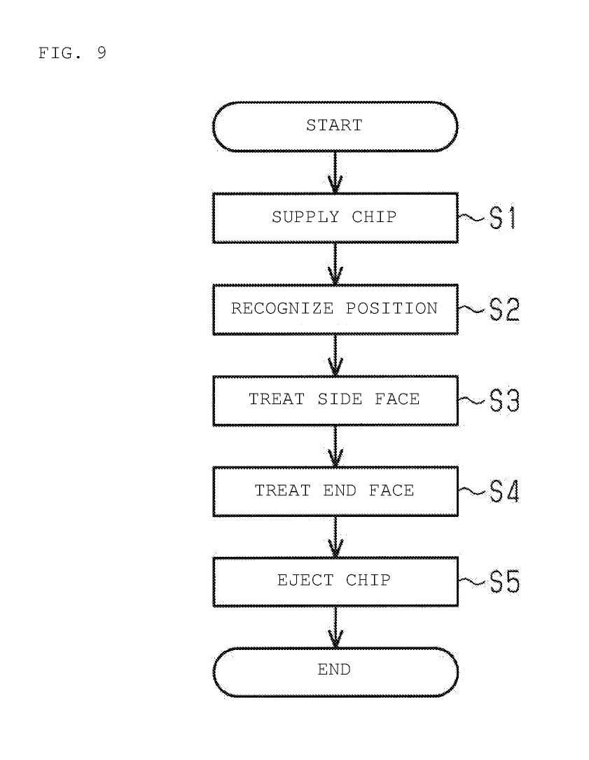

As illustrated in FIG. 8, a treatment apparatus 10 includes a control device 51 serving as a control system, a part feeder 11, a separating pin drive unit 52, a motor 40, a camera 53 serving as a photographing system, an illumination device 54, a laser device 13, a vacuum pump 55, and a charging pump 56.

The separating pin drive unit 52 is a solenoid, for example. The control device 51 controls the separating pin drive unit 52 so as to vertically move a separating pin 14b illustrated in FIG. 4.

The vacuum pump 55 is connected to a contact member 14a illustrated in FIG. 4 to be used to feed the element body 71. The vacuum pump 55 is also used to hold the element body 71 by using a suction port formed of a through-hole 32a and a communication groove 33a illustrated in FIG. 6B.

The charging pump 56 is used to supply compressed air to eject the element body 71.

The camera 53 and the illumination device 54 are used to grasp a position of the element body 71 held in the feeding rotor 20 to correct a treatment position of the laser device 13. The camera 53 and the illumination device 54 are also used to determine a side face to be treated in the element body 71. Correction of a treatment position and determination of a side face will be described below.

Subsequently, various treatment positions in the treatment apparatus 10 of the present embodiment will be described.

As illustrated in FIG. 7, the part feeder 11, the camera 53, the illumination device 54, and laser devices 13a, 13b, 13c, and 13d, are disposed around the feeding rotor 20. Black circles each illustrated on the circumference of the feeding rotor 20 indicate a treatment position. The treatment position includes a delivery position P0, a recognition position (inspection position) P1, irradiation positions P2a, P2b, P2c, and P2d, and an ejection position P3. Each of the treatment positions is set in accordance with an angle at which the holding groove 22 illustrated in FIG. 2B is formed. In the present embodiment, the holding groove 22 is formed every three degrees. Thus, each of the treatment positions is set at an angle of an integral multiple of an angle at which the holding groove 22 is formed.

Specifically, the part feeder 11 is disposed below the feeding rotor 20. The element body 71 fed by the part feeder 11 is held in the holding groove 22 (refer to FIG. 2B) of the feeding rotor 20 at the delivery position P0 positioned at the lowermost point of the feeding rotor 20.

In FIG. 7, the feeding rotor 20 is rotationally driven in a direction indicated by the arrow. The element body 71 being fed is photographed with the camera 53 at the recognition position P1. The camera 53 and the illumination device 54 each are disposed at a position corresponding to the recognition position P1. The illumination device 54 is a ring illumination device, for example. The camera 53 photographs the element body 71 and the feeding rotor 20 from an outer periphery side of the feeding rotor 20. As illustrated in FIG. 5B, the element body 71 is held in the support portion 21 of the feeding rotor 20. When the element body 71 in the shape of a rectangular parallelepiped is held, the element body 71 may be displaced in position in its longitudinal direction (the vertical direction in FIG. 5B or a direction perpendicular to an end face). Thus, the camera 53 photographs the element body 71 and the feeding rotor 20 to grasp a position of the element body 71. Specifically, the control device 51 grasps a position of the element body 71 with respect to the feeding rotor 20. Then, the control device 51 corrects a treatment position of the laser device 13 that treats a side face of the element body 71, in accordance with the grasped position of the element body 71. In the present embodiment, the laser device 13 is a laser treatment device, and the control device 51 corrects an emission angle of a laser beam of the laser device 13. This correction enables a side face of each element body 71 to be accurately treated.

In FIG. 7, the first to fourth irradiation positions P2a to P2d are set along a rotation direction of the feeding rotor 20. The first and second irradiation positions P2a and P2b each are treatment positions of treating a side face of the element body 71. The third and fourth irradiation positions P2c and P2d each are treatment positions of sequentially treating two end faces of the element body 71.

The first laser device 13a treats a surface (side face) of the element body 71 fed to the first irradiation position P2a. The first laser device 13a configured to emit a laser beam is disposed such that an optical axis La of the laser beam is to be perpendicular to a side face of the element body 71 fed to the first irradiation position P2a.

The second laser device 13b treats a surface (side face) of the element body 71 fed to the second irradiation position P2b. The second laser device 13b configured to emit a laser beam is disposed such that an optical axis Lb of the laser beam is to be perpendicular to a side face of the element body 71 fed to the second irradiation position P2b.

The first laser device 13a and the second laser device 13b are disposed such that their optical axes are to be perpendicular to the corresponding different side faces. Specifically, the adjacent two side faces 71b and 71c, or the adjacent two side faces 71c and 71d, of the element body 71 are held in the holding groove 22 in a V-shape, as illustrated in FIG. 5A. This causes a mixture of the element body 71 that is held while its side face 71a to be treated faces a rotation direction (the right direction in FIG. 5A) of the feeding rotor 20, and the element body 71 that is held while its side face 71a to be treated faces a direction opposite to the rotation direction (anti-rotation direction).

The control device 51 illustrated in FIG. 8 determines whether a side face of the element body 71 faces either the rotation direction or the anti-rotation direction on the basis of an image of the element body 71 taken with the camera 53. Then, the control device 51 controls a treatment apparatus corresponding to a direction in which the side face 71a of the element body 71 faces, on the basis of a determination result, so as to treat the side face 71a to be treated.

The third laser device 13c treats a surface (side face) of the element body 71 fed to the third irradiation position P2c. The third laser device 13c configured to emit a laser beam is disposed such that the laser beam is incident substantially perpendicular to one of end faces of the element body 71 fed to the third irradiation position P2c. The fourth laser device 13d treats a surface (side face) of the element body 71 fed to the fourth irradiation position P2d. The fourth laser device 13d configured to emit a laser beam is disposed such that the laser beam is incident substantially perpendicular to the other of end faces of the element body 71 fed to the fourth irradiation position P2d. The third and fourth laser devices 13c and 13d each may be disposed such that a laser beam is incident substantially perpendicular to the corresponding one of end faces of the element body 71 by using one or more mirrors. Likewise, the first and second laser devices 13a and 13b may be disposed such that each of their optical axes is to be perpendicular to the corresponding one of the side faces of the element body 71 by using one or more mirrors. The third and fourth laser devices 13c and 13d illustrated in FIG. 7 do not show their shapes, but show that they correspond to the irradiation positions P2c and P2d, respectively.

The element body 71 whose side faces and end faces are treated as described above is ejected at the ejection position P3 illustrated in FIG. 7.

Subsequently, a flow of treatment in a treatment apparatus will be described.

FIG. 9 illustrates a flow of treatment caused by the control device 51 of the treatment apparatus 10.

The control device 51 causes treatment of each of steps S1 to S5 illustrated in FIG. 9 to be performed, so that the element body 71 to be treated (refer to FIG. 3) is treated.

In step S1, the element body 71 is supplied to the feeding rotor 20 illustrated in FIG. 1. Then, the feeding rotor 20 suctioning the element body 71 is rotated to feed the element body 71.

In step S2, a position of the element body 71 is recognized by using the camera 53 illustrated in FIG. 7.

In step S3, a side face of the element body 71 is treated. That is, a part of the side faces of the element body 71 is treated by using the first laser device 13a or the second laser device 13b, illustrated in FIG. 7. A laser beam sweeps on a side face of the element body 71 to treat a predetermined region. For example, a laser beam with a spot diameter of 40 μm sweeps back and forth. At this time, a position of a laser beam with which the side face 71a of the element body 71 is irradiated is corrected on the basis of the position of the element body 71 recognized in step S2. This correction enables an irradiation position of a laser beam to be accurately set for each element body 71.

In step S4, an end face of the element body 71 is treated. That is, all of two end faces of the element body 71 are treated by using the third laser device 13c and the fourth laser device 13d, illustrated in FIG. 7. In step S5, the element body 71 is ejected.

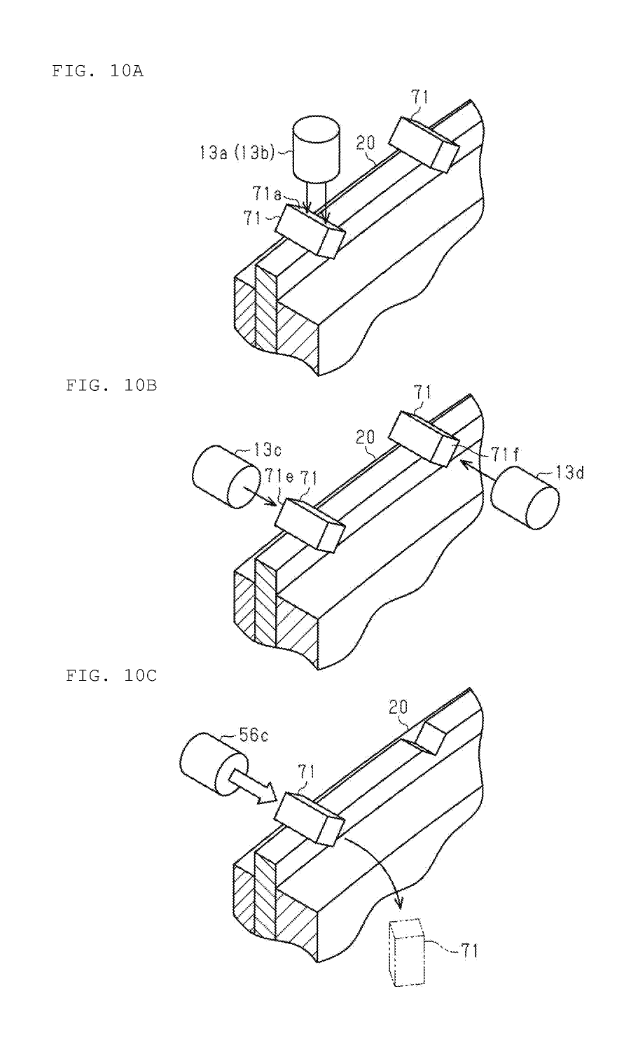

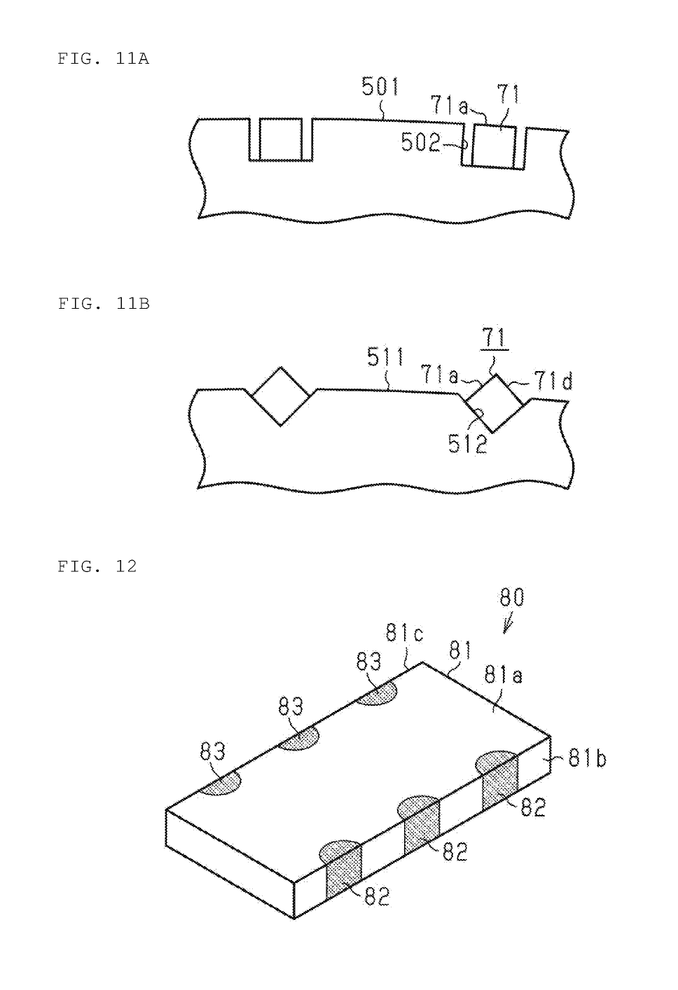

FIGS. 10A to 10C each illustrate treatment of the element body 71.

First, the side face 71a of the element body 71 is treated by using the first laser device 13a, as illustrated in FIG. 10A. The same applies to the case where the second laser device 13b is used. Next, the one end face 71e of the element body 71 is treated by using the third laser device 13c, as illustrated in FIG. 10B, and the other end face 71f of the element body 71 is treated by using the fourth laser device 13d. Then, compressed air supplied from the charging pump 56 illustrated in FIG. 8 is injected through a nozzle 56c to eject the element body 71, as illustrated in FIG. 10C.

After treating the side face 71a of the element body 71 as described above, the treatment apparatus 10 sequentially treats the two end faces 71e and 71f of the element body 71. The laser device 13 irradiates a part of a surface of the element body 71 with a laser beam, so that irradiation energy of the laser beam causes the surface of the element body 71 to be locally heated. Irradiation with the laser beam may cause the element body 71 to be displaced in position. Likewise, irradiation of an end face with a laser beam may cause this positional displacement.

Thus, it is conceivable that a position of the element body 71 is recognized just before each treatment.

Displacement in position of the element body 71 causes deterioration in accuracy of treatment of a side face 71a. Thus, after a process of recognizing a position of the element body 71 (step S2 of FIG. 9) is performed, an irradiation position is corrected in accordance with the position of the element body 71 to treat its side face (step S3 of FIG. 9), thereby preventing deterioration in accuracy of the treatment.

Meanwhile, a side face of the element body 71 is held in the feeding rotor 20. Thus, positional displacement of the element body 71 is caused in a direction along the side face. Even if the positional displacement is caused as described above, positional displacement of an end face of the element body 71 in a direction along the end face, or positional displacement of the element body 71 with respect to the feeding rotor 20, is not caused. That is, positional displacement thereof is not caused at the third irradiation position P2c and the fourth irradiation position P2d, illustrated in FIG. 7. As a result, after a side face of the element body 71 is treated (step S3 of FIG. 9), an end face thereof can be treated (step S4 of FIG. 9) without recognizing a position of the element body 71.

Subsequently, operation of the treatment apparatus 10 described above will be described.

The treatment apparatus 10 includes a feeding device 12 and a laser device 13. The feeding device 12 includes a feeding rotor 20 and a motor 40. The feeding rotor 20 is rotatably supported, and is formed in a circular shape. In an outer peripheral surface of the feeding rotor 20, a support portion 21 extending in a circumferential direction of the feeding rotor 20 is formed, and holding grooves 22 are formed in the support portion 21 at equal angular intervals. The laser device 13 treats a surface of the element body 71 fed to a treatment position. The control device 51 controls the motor 40 so as to stop the feeding rotor 20 at every predetermined angle (an angle at which the holding groove 22 is formed) and so as to feed the element body 71 to a treatment position. Then, the control device 51 controls the laser device 13 so as to treat a surface of the element body 71.

According to this structure, chips are fed by the circular feeding rotor 20 so that each of their element bodies 71 is treated at a predetermined treatment position. As a result, treatment can be efficiently performed, or capacity in the treatment can be improved, as compared with a case where chips disposed on a table are treated, for example. In addition, the feeding rotor 20 is rotationally driven to feed element bodies 71, so that the plurality of element bodies 71 can be treated without changing position of the laser device 13, thereby enabling improvement in treatment capacity.

In the treatment apparatus 10, the control device 51 stops the feeding rotor 20 at every angle at which the holding groove 22 is formed, and causes a surface of the element body 71 stopped at a treatment position to be treated. As described above, the feeding rotor 20 is stopped at every angle at which the holding groove 22 is formed, so that the element body 71 can be reliably stopped at the treatment position. Then, the element body 71 stopped at the treatment position can be accurately treated.

The element body 71 is a ceramic element, and the laser device 13 is a laser treatment device that locally heats a surface of the ceramic element to reduce resistance in a part of the ceramic element. Thus, the element body 71 being a ceramic element is irradiated with a laser beam, so that a surface of the minute element body 71 can be locally and accurately heated. When the ceramic element is locally heated as described above to reduce resistance in its local portion, an external electrode can be formed by applying plating to the local portion.

The holding groove 22 of the feeding rotor 20 is formed such that a part of each of the adjacent two side faces of the element body 71 in the shape of a rectangular parallelepiped is to be in contact with the holding groove 22 and all of two side faces to be in non-contact therewith project from the holding groove 22. The laser device 13 includes a first laser device 13a and a second laser device 13b, corresponding to two respective side faces that are not held, and a third laser device 13c and a fourth laser device 13d, corresponding to two respective end faces.

In the element body 71 held in the feeding rotor 20, an end face and a side face of the element body 71 can be treated. Then, the element body 71 is held such that its two side faces in non-contact with the holding groove 22 project from the holding groove 22, and thus the feeding rotor 20 can be prevented from being affected by treatment in the laser device 13.

The control device 51 controls any one of the first laser device 13a and the second laser device 13b, the third laser device 13c, and the fourth laser device 13d, so as to treat one side face and two end faces of the element body 71. The third and fourth laser devices 13c and 13d can treat one side face and two end faces of the element body 71. When one of the side faces of the element body 71, in non-contact with the holding groove 22, is a face to be treated, the first laser device 13a or the second laser device 13b is controlled for treatment depending on a state (posture) of the element body 71 held in the holding groove 22. This enables a side face of the element body 71 being fed to be treated without being affected by a state of the element body 71.

The control device 51 controls the first laser device 13a or the second laser device 13b on the basis of a photographed result of the camera 53 so as to treat a side face of the element body 71, corresponding to the controlled laser device 13. One of two side faces of the element body 71, in non-contact with the holding groove 22, to be treated, is grasped, and the first treatment device 13a or the second treatment device 13b corresponding to the face to be treated is controlled so as to treat the face, so that the side face of the element body 71 being fed can be treated without being affected by a state of the element body 71.

Along a rotation direction of the feeding rotor 20, a treatment position, at which the corresponding one of the first to fourth laser devices 13a to 13d treats the element body 71, is set. The element body 71 is held in the holding groove 22 while its side faces are in contact with the holding groove 22. When a surface of the element body 71 is treated, the element body 71 may be displaced in position. The element body 71 is displaced in position along the side faces held in the holding groove 22. However, the end faces of the element body 71 are not displaced in position as viewed from a direction along the side faces of the element body 71. Thus, treating the end faces after the side faces are treated enables the respective faces to be accurately treated.

Here, a comparative example in contrast to the present embodiment will be described.

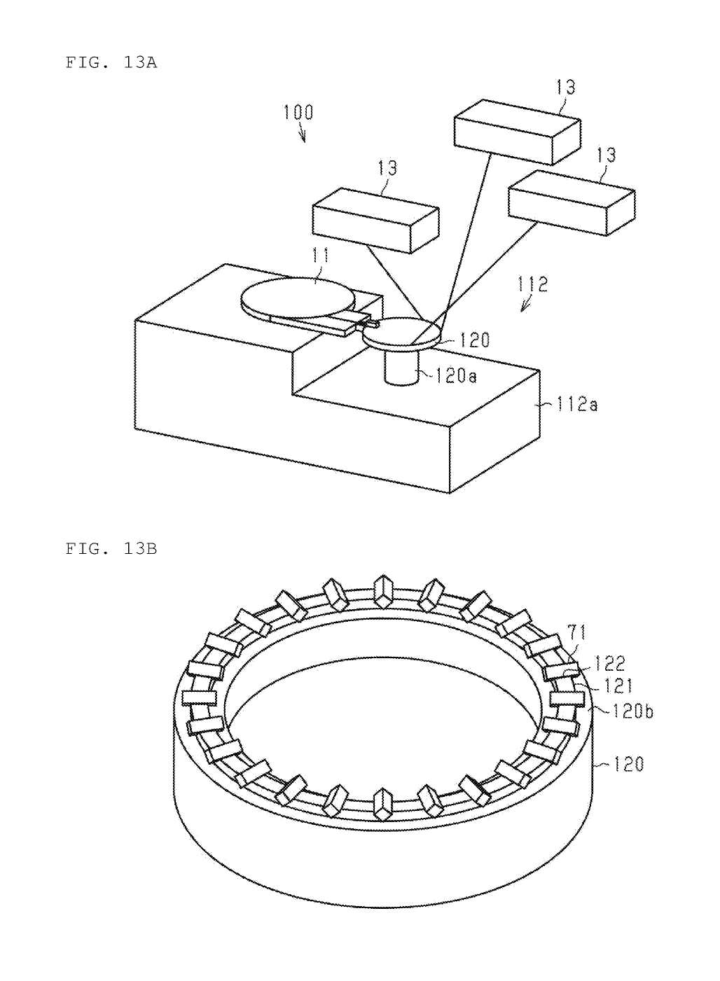

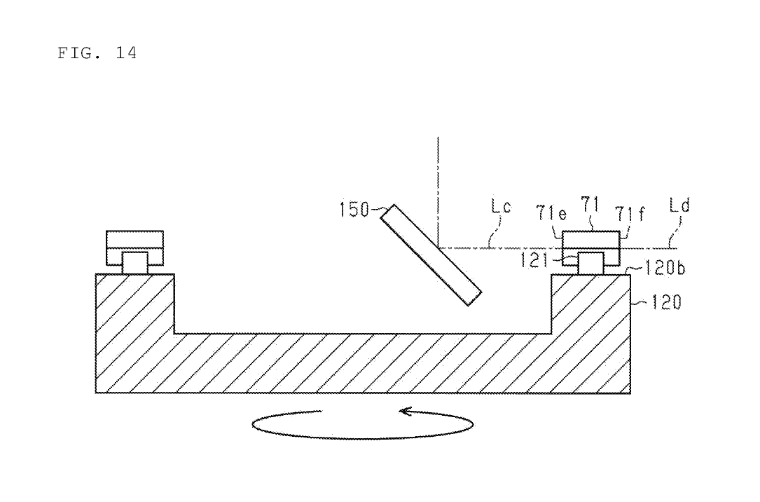

In a feeding rotor 501 illustrated in FIG. 11A, a holding groove 502 in the shape of a rectangle is formed, and the element body 71 is housed in the holding groove 502. In this case, each of one side face and two end faces of the element body 71 is irradiated with a laser beam. Thus, when the element body 71 is not accurately aligned, the side face cannot be treated. In addition, the feeding rotor 501 may be irradiated with a laser beam for treating the side face. The laser beam being emitted deteriorates the feeding rotor 501, so that a period of use, or a life time, of the feeding rotor 501 is shortened.

In a feeding rotor 511 illustrated in FIG. 11B, a holding groove 512 is larger in size than the element body 71. In this case, all of two side faces 71a and 71d in non-contact with the holding groove 512, of the side faces of the element body 71, do not project from the holding groove 512. This may cause the feeding rotor 511 to be irradiated with a laser beam for treating the side face 71a. The laser beam being emitted deteriorates the feeding rotor 511, so that a period of use, or a life time, of the feeding rotor 511 is shortened.

In contrast to the comparative example described above, in the treatment apparatus 10 of the present embodiment, the feeding rotor 20 is supported to be able to vertically rotate by having a rotating shaft supported horizontally, and is provided on its outer peripheral surface with a support portion 21 extending along its circumferential direction. The holding groove 22 is provided in an outer peripheral surface of the support portion, and is formed so as to extend in a thickness direction of the feeding rotor 20. The support portion 21 is formed such that both end faces of the element body 71 held in the holding groove 22 project from the support portion 21 in a direction parallel to the rotating shaft of the feeding rotor 20.

The feeding rotor 20 vertically (longitudinally) rotates by using the rotating shaft supported horizontally. The element body 71 is held in the support portion 21 of the feeding rotor 20 that vertically rotates as described above such that its end faces project in a direction parallel to the rotating shaft. Thus, the end faces of the element body 71 can be easily treated. The element body 71 is held such that its end faces project from the support portion 21, and thus the support portion 21 or the feeding rotor 20 can be prevented from being affected by treatment in the laser device 13.

The control device 51 grasps a position of the element body 71 on the basis of a photographed result of the camera 53, and corrects a position of treatment to be applied to the element body 71 by the laser device 13 on the basis of the grasped position of the element body 71.

When the element body 71 is fed to the feeding rotor 20 from the part feeder 11, the element body 71 may be displaced in position. For that, the camera 53 photographs the element body held by the feeding rotor 20 to grasp a position of the element body 71, and a treatment position is corrected in accordance with the grasped position, thereby enabling treatment with high accuracy.

As described above, the present embodiment achieves effects described below.

(1-1) The treatment apparatus 10 includes a feeding device 12 and a laser device 13. The feeding device 12 includes a feeding rotor 20 and a motor 40. The feeding rotor 20 is rotatably supported, and is formed in a circular shape. In an outer peripheral surface of the feeding rotor 20, a support portion 21 extending in a circumferential direction of the feeding rotor 20 is formed, and holding grooves 22 are formed in the support portion 21 at equal angular intervals.

The laser device 13 treats a surface of the element body 71 fed to a treatment position. The control device 51 controls the motor 40 so as to stop the feeding rotor 20 at every predetermined angle (an angle at which the holding groove 22 is formed) and so as to feed the element body 71 to a treatment position. Then, the control device 51 controls the laser device 13 so as to treat a surface of the element body 71.

According to this structure, chips are fed by the circular feeding rotor 20 so that each of their element bodies 71 is treated at a predetermined treatment position. As a result, treatment can be efficiently performed, or capacity in the treatment can be improved, as compared with a case where chips disposed on a table are treated, for example. In addition, the feeding rotor 20 is rotationally driven to feed element bodies 71, so that the plurality of element bodies 71 can be treated without changing position of the laser device 13, thereby enabling improvement in treatment capacity.

(1-2) In the treatment apparatus 10, the control device 51 stops the feeding rotor 20 at every angle at which the holding groove 22 is formed, and causes a surface of the element body 71 stopped at a treatment position to be treated. As described above, the feeding rotor 20 is stopped at every angle at which the holding groove 22 is formed, so that the element body 71 can be reliably stopped at the treatment position. Then, the element body 71 stopped at the treatment position can be accurately treated.

(1-3) The element body 71 is a ceramic element, and the laser device 13 is a laser treatment device that locally heats a surface of the ceramic element to reduce resistance in a part of the ceramic element.

Thus, the element body 71 being a ceramic element is irradiated with a laser beam, so that a surface of the minute element body 71 can be locally and accurately heated. When the ceramic element is locally heated as described above to reduce resistance in its local portion, an external electrode can be formed by applying plating to the local portion.

(1-4) The holding groove 22 of the feeding rotor 20 is formed such that a part of each of the adjacent two side faces of the element body 71 in the shape of a rectangular parallelepiped is to be in contact with the holding groove 22 and all of two side faces to be in non-contact therewith project from the holding groove 22. The laser device 13 includes a first laser device 13a and a second laser device 13b, corresponding to two respective side faces that are not held, and a third laser device 13c and a fourth laser device 13d, corresponding to two respective end faces.

In the element body 71 held in the feeding rotor 20, an end face and a side face of the element body 71 can be treated. Then, the element body 71 is held such that its two side faces in non-contact with the holding groove 22 project from the holding groove 22, and thus the feeding rotor 20 can be prevented from being affected by treatment in the laser device 13.

(1-5) The control device 51 controls any one of the first laser device 13a and the second laser device 13b, the third laser device 13c, and the fourth laser device 13d, so as to treat one side face and two end faces of the element body 71. The third and fourth laser devices 13c and 13d can treat one side face and two end faces of the element body 71. When one of the side faces of the element body 71, in non-contact with the holding groove 22, is a face to be treated, the first laser device 13a or the second laser device 13b is controlled for treatment depending on a state (posture) of the element body 71 held in the holding groove 22, and thus a side face of the element body 71 being fed can be treated without being affected by a state of the element body 71.

(1-6) The control device 51 controls the first laser device 13a or the second laser device 13b on the basis of a photographed result of the camera 53 so as to treat a side face of the element body 71, corresponding to the controlled laser device 13. One of two side faces of the element body 71, in non-contact with the holding groove, to be treated, is grasped, and the first laser device 13a or the second laser device 13b corresponding to the face to be treated is controlled so as to treat the face, so that the side face of the element body 71 being fed can be treated without being affected by a state of the element body 71.

When the first laser device 13a or the second laser device 13b treats a side face of the element body 71, the element body 71 may be displaced in position. This positional displacement is caused in a direction along the side face of the element body 71, or in a direction orthogonal to end faces of the element body 71. The amount of the positional displacement caused in the element body 71 is less than a focus range of a laser beam emitted from each of the third and fourth laser devices 13c and 13d used to treat an end face of the element body 71. Thus, the end face of the element body 71 can be treated with high accuracy.

(1-7) The feeding rotor 20 is supported to be able to vertically rotate by having the rotating shaft supported horizontally, and is provided on its outer peripheral surface with the support portion 21 extending along its circumferential direction. The holding groove 22 is provided in an outer peripheral surface of the support portion, and is formed so as to extend in a thickness direction of the feeding rotor 20. The support portion 21 is formed such that both end faces of the element body 71 held in the holding groove 22 project from the support portion 21 in the direction parallel to the rotating shaft of the feeding rotor 20.

The feeding rotor 20 vertically (longitudinally) rotates by using the rotating shaft supported horizontally. The element body 71 is held in the support portion 21 of the feeding rotor 20 that vertically rotates as described above such that its end faces project in a direction parallel to the rotating shaft. Thus, the end faces of the element body 71 can be easily treated. The element body 71 is held such that its end faces project from the support portion 21, and thus the support portion 21 or the feeding rotor 20 can be prevented from being affected by treatment in the laser device 13.

(1-8) The control device 51 grasps a position of the element body 71 on the basis of a photographed result of the camera 53, and corrects a position of treatment to be applied to the element body 71 by the laser device 13 on the basis of the grasped position of the element body 71.

When the element body 71 is fed to the feeding rotor 20 from the part feeder 11, the element body 71 may be displaced in position. For that, the camera 53 photographs the element body held by the feeding rotor 20 to grasp a position of the element body 71, and a treatment position is corrected in accordance with the grasped position, thereby enabling treatment with high accuracy.

### Second Embodiment

A second embodiment will be described below.

In the present embodiment, the component same as that of the embodiment described above is designated by the same reference sign to eliminate a part or all of the description of the component.

As illustrated in FIG. 13A, a treatment apparatus 100 includes a part feeder 11, a feeding device 112, and a laser device 13 serving as a treatment device. FIG. 13A illustrates three laser devices 13. A straight line connecting each of the laser devices 13 to the feeding device 112 indicates a relationship between each of the laser devices 13 and the feeding device 112, and does not indicate a treatment position by each of the laser devices 13.

The feeding device 112 includes a feeding rotor 120, and a rotating shaft 120a that supports the feeding rotor 120. In the present embodiment, the rotating shaft 120a is vertically supported in a body portion 112a of the feeding device 112. Thus, the feeding rotor 120 rotates in a horizontal direction (lateral direction).

As illustrated in FIG. 13B, a support portion 121 extending along a circumferential direction of the feeding rotor 120 is formed in a top face 120b of the feeding rotor 120 formed in a circular shape. Holding grooves 122 are formed in the support portion 121, and the element body 71 is held in each of the holding grooves 122. In FIG. 13B, the element body 71 is illustrated in an enlarged manner to easily understand a holding state of the element body 71, so that the number of element bodies 71 illustrated is less than the number of element bodies 71 being actually held.

The holding groove 122 is formed so as to extend along a radial direction of the feeding rotor 120. The holding groove 122 is formed in a V-shape as viewed from the radial direction of the feeding rotor 120 so as to hold the element body 71 to be fed at an angle.

At this time, the element body 71 is held such that its side face 71a to be treated is positioned on an upper face side of the feeding rotor 120. In other words, the above part feeder 11 aligns the element body 71 such that the side face 71a to be treated is positioned on the upper face side of the feeding rotor 120.

The holding grooves 122 are formed in an edge portion of the feeding rotor 120 at equal intervals (at equal angular intervals). The holding groove 122 is provided at its bottom with a suction port (not illustrated). As with the first embodiment, the element body 71 is held in the holding groove 122 while being suctioned by a vacuum pump.

As with the first embodiment, a central portion of the element body 71 in its longitudinal direction is held in the holding groove 122 in the support portion 121. The holding groove 122 is formed so as to extend along a radial direction of the feeding rotor 120. This allows the element body 71 to be held such that its end faces each project radially either outward or inward of the support portion 121.

As illustrated in FIG. 14, the end face 71e of the element body 71 supported in the feeding rotor 120 is irradiated with a laser beam Lc (illustrated by a dashed line) by using a mirror 150 provided inward of the feeding rotor 120. In addition, the end face 71f of the element body 71 is directly irradiated with a laser beam Ld from outward of the feeding rotor 120.

As described above, the present embodiment achieves an effect described below in addition to the effects of the first embodiment.

(2-1) In the treatment apparatus 100 of the present embodiment, the feeding rotor 120 is supported to be able to horizontally rotate by having a rotating shaft supported vertically, and is provided on its top face with the annular support portion 121 extending along its circumferential direction. The holding groove 122 is provided on the top face of the support portion 121, and is formed so as to extend in the radial direction of the feeding rotor 120. The support portion 121 is formed such that both end faces of the element body 71 held in the holding groove 122 project radially either outward or inward from the support portion 121.

As described above, the feeding rotor 120 horizontally (laterally) rotates by using the rotating shaft supported vertically. The element body 71 is held by the support portion 121 of the feeding rotor 120 that horizontally rotates as described above, so that the element body 71 can be fed in a stable state. The element body 71 is held such that its end faces project from the support portion 121, and thus the support portion 121 or the feeding rotor 120 can be prevented from being affected by treatment in the laser device 13.

The first and second embodiments described above may be practiced by an aspect below.
In the first and second embodiments described above, while the treatment apparatuses 10 and 100 each are configured to treat side faces and end faces of the element body 71, a shape and a face to be treated of the element body 71 to be treated are not limited to those of the embodiments described above. For example, only one of the side faces of the element body 71 may be treated. In addition, only end faces of the element body 71 may be treated.

An electronic component 80 illustrated in FIG. 12 includes external electrodes 82 provided in side faces 81a and 81b of an element body 81, and external electrodes 83 provided in side faces 81a and 81c. When the external electrodes 82 and 83 of the element body 81 are formed, a treatment apparatus may treat a part of the side faces 81a, 81b, and 81c of the element body 81. For the element body 81, two side faces thereof (e.g., the side faces 81a and 81b) are treated, and the element body 81 is ejected, and then is put into the treatment apparatus 10 again to treat a residual side face (e.g., the side face 81c), so that the three side faces can be treated.
In the first and second embodiments described above, while the treatment apparatuses 10 and 100 each include the laser device 13 that locally heats a surface of the element body 71 to form external electrodes 72 and 73 illustrated in FIG. 3A, a system for performing another treatment may be fabricated. For example, when a chip inductor is formed by forming an electrode formed in a surface into a desired shape by using laser irradiation, or the like, a system for performing the treatment can be fabricated. In addition, a system for showing a character, such as a model number, in a surface of a chip transistor or the like, can be fabricated. Further, the treatment apparatuses 10 and 100 may be configured to treat the element body 71 by using a device other than a laser treatment device, as the laser device 13. For example, a device for applying liquid or resin by using a jet dispenser may be used.
In the first and second embodiments described above, any treatment other than treatment for irradiating a surface of the element body 71 with a laser beam from the laser device 13 may be applied to the element body 71 fed by each of the feeding rotors 20 and 120. For example, the treatment as described above includes a treatment for inspecting an appearance of the element body 71 having reached a treatment position, and a treatment for inspecting a performance of the element body 71 having reached the treatment position. In these cases, a device for performing each inspection corresponds to a treatment device.

### Third Embodiment

A third embodiment will be described below. A chip-like electronic component to be treated in the present embodiment is different in shape from the electronic component 70 treated in each of the first and second embodiments.

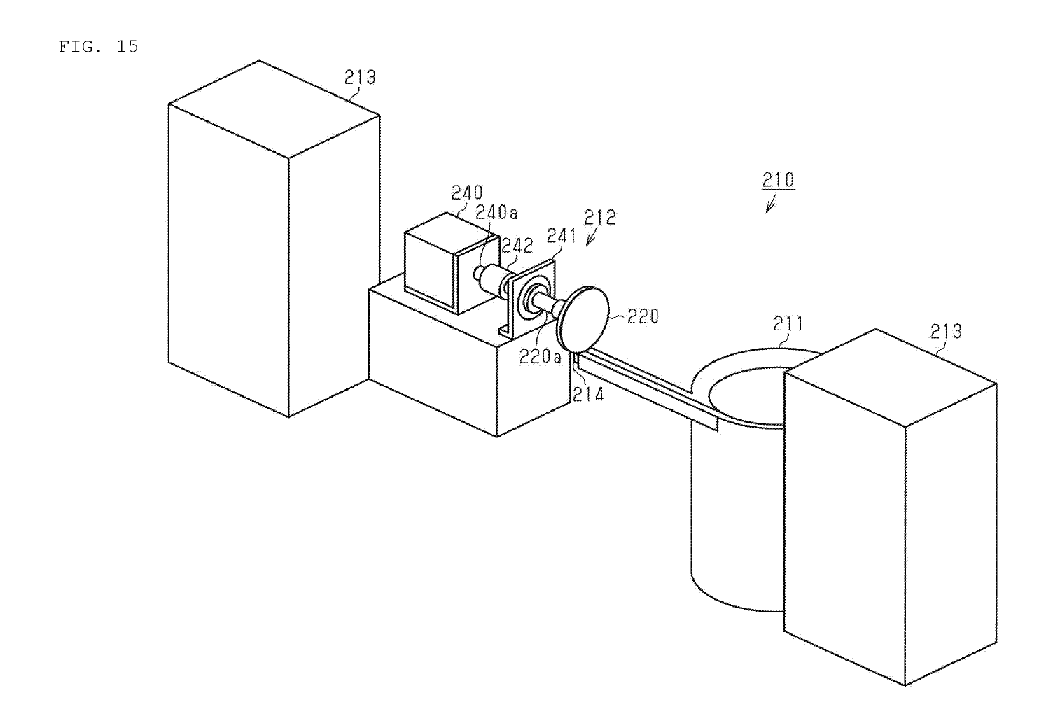

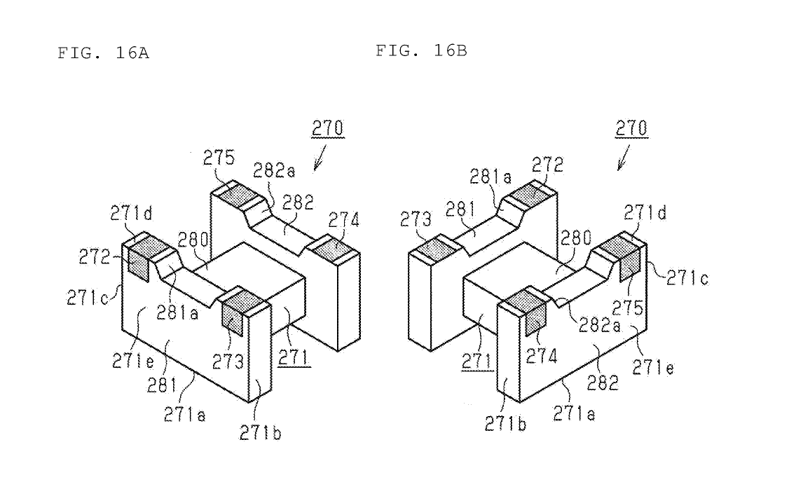

As illustrated in FIG. 15, a treatment apparatus 210 includes a part feeder 211 serving as a supply system, a feeding device 212 serving as a feeding system, and a laser device 213 serving as a treatment device. The treatment apparatus 10 has a plurality of the laser devices 213. While FIG. 15 illustrates the two laser devices 213, the number of treatment devices suitable for treatment is provided. In the description below, when laser devices are individually described, each of the laser devices is designated as a reference sign, and a reference numeral “213” is used in a common description of a laser device. In the present embodiment, the part feeder 211 and the feeding device 212 constitute an example of a “component feeder”.

The part feeder 211 sequentially supplies an object to be treated by the laser device 213 to the feeding device 212 by using vibration. The object to be treated is an element body constituting an electronic component. The feeding device 212 feeds a supplied element body to a treatment position. In the present embodiment, the treatment apparatus 210 has a plurality of the laser devices 213, and a treatment position is set for each of the laser devices 213. The feeding device 212 sequentially feeds the element body to each treatment position, and the laser device 213 treats the element body being fed, or emits a laser beam. The treated element body is fed to an ejection position by the feeding device 212, and is ejected.

Here, the element body to be treated will be described.

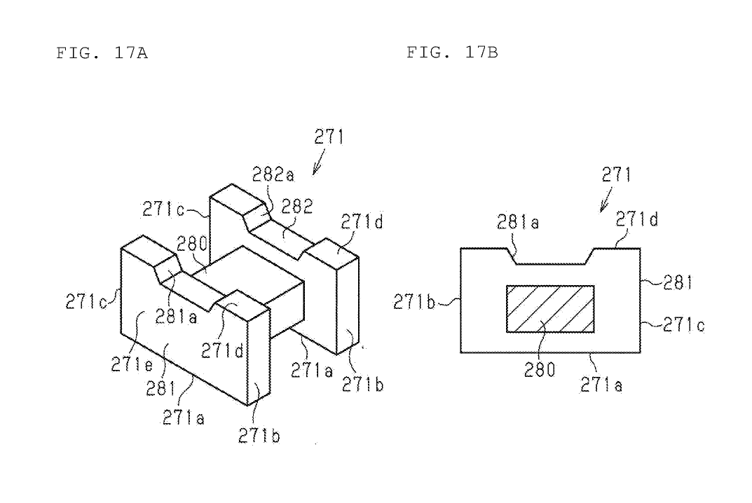

As illustrated in FIGS. 16A and 16B, an electronic component 270 of the present embodiment is an electronic component mounted on a surface of a substrate or the like, and is a chip ferrite bead, for example. As the electronic component 270, a chip inductor or a chip capacitor may be used, for example.

The electronic component 270 includes an element body 271 to be treated, and four external electrodes 272, 273, 274, and 275 formed on a surface of the element body 271. As illustrated in FIGS. 17A and 17B, the element body 271 includes a shank 280 in the shape of a rectangular parallelepiped, a first flange 281 connected to one end of the shank 280, and a second flange 282 connected to the other end of the shank 280. While there is no illustration, a plurality of (e.g., two) coils is wound around the shank 280. The corresponding ends of the coils are fixed to the external electrodes 272 to 275.

Each of the flanges 281 and 282 is in the shape of a substantially rectangular parallelepiped in plan view. That is, as illustrated in FIGS. 17A and 17B, the flanges 281 and 282 each include a first side face 271a, a second side face 271b connected to one end of the first side face 271a, a third side face 271c connected to the other end of the first side face 271a, and a fourth side face 271d connected to the second side face 271b and the third side face 271c. When one of opposite ends of the second side face 271b, connected to the first side face 271a, is indicated as one end, the fourth side face 271d is connected to the other end of the second side face 271b. When one of opposite ends of the third side face 271c, connected to the first side face 271a, is indicated as one end, the fourth side face 271d is connected to the other end of the third side face 271c. In addition, the flanges 281 and 282 each include an end face 271e connected to the first side face 271a, the second side face 271b, the third side face 271c, and the fourth side face 271d.

In the side faces 271a to 271d of each of the flanges 281 and 282, the first side face 271a and the second side face 271b each are planes. Meanwhile, recessed portions 281a and 282a each are formed in a central portion of the corresponding one of the fourth side faces 271d in its longitudinal direction.

The electronic component 270, or the element body 271 is a very small component. For example, the shank 280 has a size of 1.4 mm by 0.8 mm by 2.0 mm, for example. Each of the flanges 281 and 282 has a size of 2.5 mm by 1.3 mm by 0.6 mm, for example. In this case, a length of the first side face 271a in its longitudinal direction corresponds to 2.5 mm, and a length of each of the second side face 271b and the third side face 271c in its longitudinal direction corresponds to 1.3 mm. That is, the first side face 271a is longer than the second side face 271b and the third side face 271c in the present embodiment.

The element body 271 is a sintered ceramic element, for example. The ceramic element is formed of ferrite material containing nickel (Ni) and zinc (Zn). As the ferrite material, Ni—Zn-based ferrite containing Ni and Zn as main components, and Ni—Cu—Zn-based ferrite containing Ni, Zn, and copper (Cu) as main components, are available, for example. The element body 271 can be acquired by compressing and sintering the ferrite material described above, for example.

As illustrated in FIGS. 16A and 16B, the external electrodes 272 and 273 of the external electrodes 272 to 275 are formed in the first flange 281 at intervals. Meanwhile, the residual external electrodes 274 and 275 are formed in the second flange 282 at intervals. Each of the external electrodes 272 to 275 is formed by plating. As material of the external electrodes 272 to 275, Cu, aurum (Au), Ag, Pd, Ni, and Sn are available, for example. The external electrodes 272 to 275 also may be formed of multilayer plated metal.

The external electrodes 272 to 275 are formed by plating after local heat treatment is applied to the flanges 281 and 282 of the element body 271. The laser device 213 described above is used to apply the local heat treatment to the flanges 281 and 282. As the laser device 13, a YVO4 laser device (with a wavelength of 1064 nm) is available, for example. As the treatment apparatus, an electron beam irradiation device, an image furnace, and the like are also available. The laser device 213 is preferable in that an irradiation position on the element body 271 can be quickly changed.

Local heating by the laser device 213 causes a ceramic element in a surface of the flanges 281 and 282 of the element body 271 to change in properties. The local heating causes an insulating material (ferrite) constituting the ceramic element to change in properties, so that a low resistance portion with a resistance lower than that of the insulating material is formed.

The element body 271 including the low resistance portion is immersed in a plating solution so that electrolytic plating is applied to the element body 271. The low resistance portion with conductivity has an electric current density higher than that in other portions in the element body 271, so that a plating metal is deposited on a surface of the low resistance portion. The plating metal deposited as described above enables the external electrodes 272 to 275 to be formed.

As described above, the treatment apparatus 210 of the present embodiment sequentially feeds the element body 271 constituting the electronic component 270 described above, and the laser device 213 treats the element body 271. Feeding of the element body 271 will be described below.

As illustrated in FIG. 15, the treatment apparatus 210 includes the part feeder 211, and the feeding device 212. The part feeder 211 aligns the above element bodies 271 (refer to FIG. 17A) by using vibration, and feeds them. In the present embodiment, the part feeder 211 aligns the element bodies 271 such that the fourth side face 271d to be treated of each of the side faces 271a to 271d of the corresponding one of the flanges 281 and 282 of each of the element bodies 271, faces downward. The element body 271 fed by the part feeder 211 is delivered to the feeding device 212 through a non-vibration portion 214 provided at a leading end of the part feeder 211.

The feeding device 212 includes a feeding rotor 220, and a motor 240 serving as a drive unit for rotationally driving the feeding rotor 220. The feeding rotor 220 has a diameter of 70 mm in size, for example. The diameter is relatively small, so that positional displacement caused by vibration of the feeding rotor 220 can be reduced even if the feeding rotor 220 is rotationally driven at high speed (e.g., 4000 rpm). The feeding rotor 220 has a rotating shaft 220a that is rotatably supported by a supporting stand 241 including a bearing. The rotating shaft 220a is coupled to an output shaft 240a of the motor 240 with a coupling 242. The coupling 242 allows misalignment between the rotating shaft 220a of the feeding rotor 220 and the output shaft 240a of the motor 240.

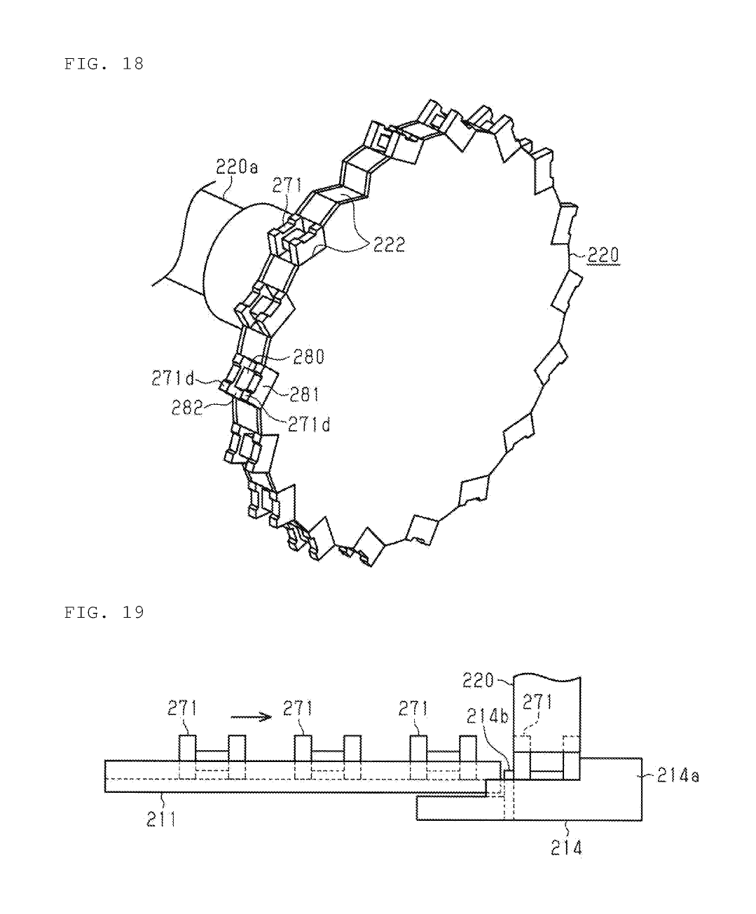

As illustrated in FIG. 18, a plurality of holding grooves 222 is provided on an outer periphery side of the feeding rotor 220 formed in a circular shape, along a circumferential direction of the feeding rotor 220. The feeding rotor 220 can hold element bodies 271 by using the corresponding holding grooves 222. While details are described below, the element body 271 is held in the holding groove 222 by vacuum suction. In FIG. 18, the holding grooves 222 and the element bodies 271 are illustrated in an exaggerated manner to easily understand a shape of each of the holding grooves 222, and a holding state of each of the element bodies 271 in the corresponding one of the holding grooves 222.

The holding groove 222 is formed so as to extend in a direction parallel to the rotating shaft of the feeding rotor 220. The holding groove 222 is formed in a V-shape as viewed from a direction of the rotating shaft of the feeding rotor 220 so as to hold the element body 271 to be fed at an angle. At this time, the element body 271 is held such that a fourth side face 271d of each of flanges 281 and 282 of the element body 271, or a side to be treated of the element body 271, is positioned radially outside of the feeding rotor 220. In other words, the above part feeder 211 aligns the element body 271 such that the fourth side face 271d of each of the flanges 281 and 282 faces radially outward of feeding rotor 220. In addition, the part feeder 211 may align the element body 271 such that the fourth side face 271d of each of the flanges 281 and 282 faces a constant direction.

The holding grooves 222 are formed in a radially outward edge portion of the feeding rotor 220 at equal intervals (at equal center angular intervals) in the circumferential direction. For example, the holding grooves 222 are formed every three degrees. That is, 120 holding grooves 222 are formed in the feeding rotor 220. This allows 120 element bodies 271 to be treated in one turn of the feeding rotor 220.

Subsequently, delivery of the element body 271 from the part feeder 211 to the feeding rotor 220 will be described.

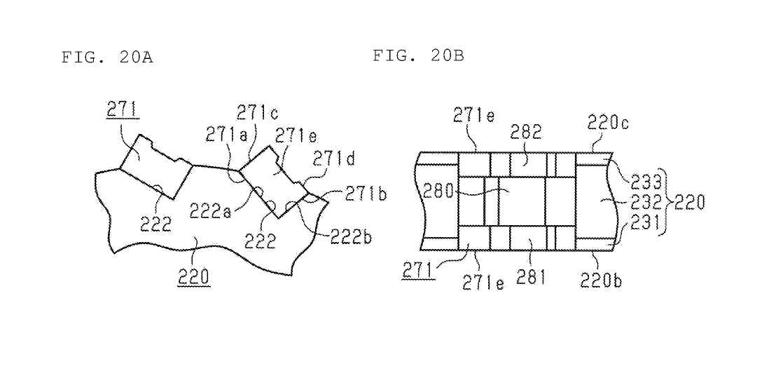

As illustrated in FIG. 19, the part feeder 211 is provided at its leading end with the non-vibration portion 214. The non-vibration portion 214 includes a contact member 214a with which each of the element bodies 271 is brought into contact for positioning, and a separating pin 214b for separating each of the element bodies 271. The separating pin 214b is moved by a separating pin drive unit described below, in a vertical direction of FIG. 19. The contact member 214a is coupled to a vacuum pump described below. When the separating pin 214b descends, the element body 271 is suctioned by the contact member 14a. Then, the separating pin 214b rises to separate the element body 271 to be fed subsequently from the element body 271 suctioned by the contact member 214a. The element body 271 suctioned by the contact member 214a is brought into contact with the contact member 214a, and is positioned by the contact member 214a. Then, the element body 271 is held in the holding groove 222 illustrated in FIG. 18.

With reference to FIGS. 20A and 20B, a state of the element body 271 held in the feeding rotor 220 will be described. As illustrated in FIG. 20A, the element body 271 is held in the holding groove 222 such that the first side face 271a and the second side face 271b of each of the flanges 281 and 282 of the element body 271 are supported. In addition, as illustrated in FIG. 20B, the element body 271 is held in the holding groove 222 such that a first face 220b of the feeding rotor 220 is flush with the end face 271e of the first flange 281, as well as a second face 220c of the feeding rotor 220 is flush with the end face 271e of the second flange 282, in an extending direction of the rotating shaft 220a.

Subsequently, an example of structure of the feeding rotor 220 will be described.

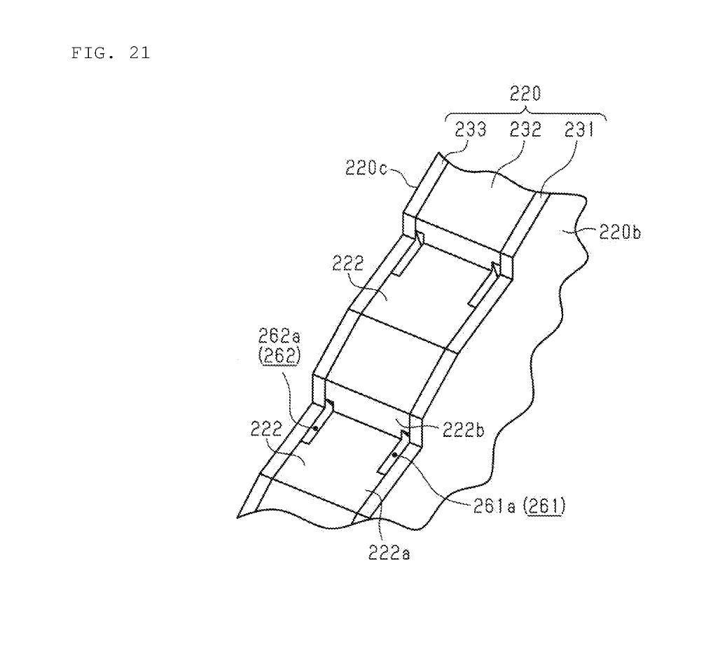

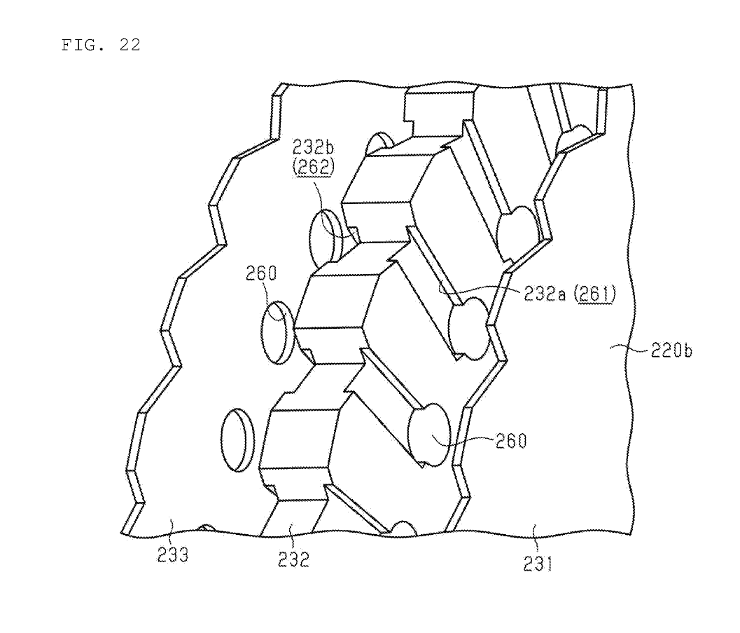

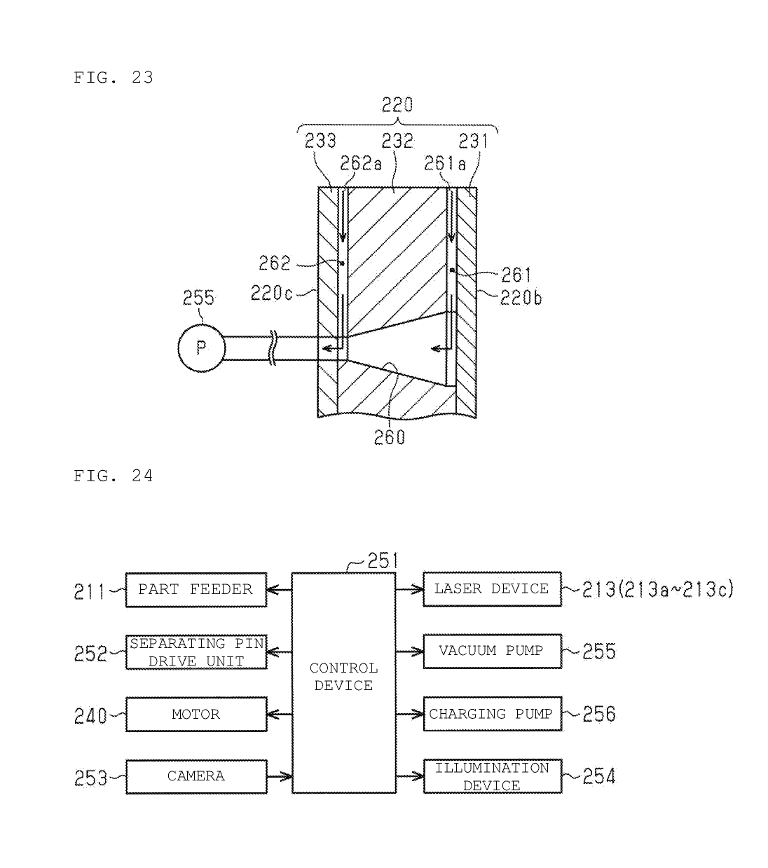

As illustrated in FIGS. 21 and 22, the feeding rotor 220 is formed of three disks 231, 232, and 233 stacked with each other in an axial direction that is the extending direction of the rotating shaft 220a. The second disk 232 positioned in the middle of the disks 231 to 233 has a thickness thicker than that of each of the residual two disks, or the first disk 231 and the third disk 233. The first disk 231 and the third disk 233 each have a thickness thinner than a thickness of each of the flanges 281 and 282 of the element body 271.

In the present embodiment, the second disk 232 has a diameter identical to a diameter of each of the first disk 231 and the third disk 233. Each of the holding grooves 222 provided in the radially outward edge portion of the feeding rotor 220 includes a first holding face 222a that is brought into surface contact with the first side faces 271a of each of the flanges 281 and 282, and a second holding face 222b that is brought into surface contact with the second side face 271b of each of the flanges 281 and 282. Each of the holding grooves 222 is formed in a shape suitable for a shape of each of the flanges 281 and 282 of the element body 271 held in the holding groove 222. In the present embodiment, the first side face 271a is longer than the second side faces 271b in each of the flanges 281 and 282. Thus, each of the holding grooves 222 is formed such that the first holding face 222a is longer than the second holding face 222b. For example, a length of the first holding face 222a in its longitudinal direction is identical to a length of the first side face 271a in its longitudinal direction, and a length of the second holding face 222b in its longitudinal direction is identical to a length of the second side face 271b in its longitudinal direction. In addition, a length of the first holding face 222a in its longitudinal direction may be slightly more than a length of the first side face 271a in its longitudinal direction, and a length of the second holding face 222b in its longitudinal direction may be slightly more than a length of the second side face 271b in its longitudinal direction. Further, an angle made by the first holding face 222a and the second holding face 222b is equal to an angle made by the first side face 271a and the second side face 271b in each of the flanges 281 and 282. This enables not only all of the first side face 271a of each of the flanges 281 and 282 to be brought into surface contact with the first holding face 222a, but also all of the second side face 271b of each of the flanges 281 and 282 to be brought into surface contact with the second holding face 222b.

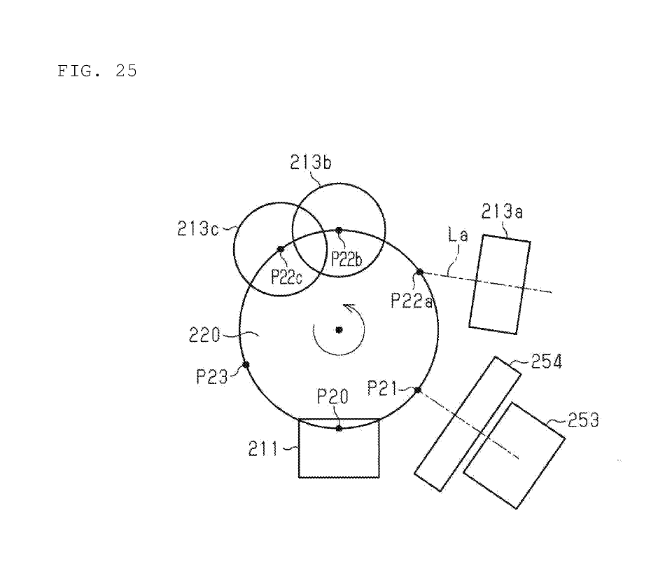

As illustrated in FIGS. 22 and 23, the feeding rotor 220 is provided with a plurality of suction holes 260 that extends through the second disk 232 and the third disk 233 in an axial direction of each of the disks, or in a thickness direction of each of the disks 232 and 233. The respective suction holes 260 are disposed along the circumferential direction of the feeding rotor 220 at equal angular intervals. The number of the suction holes 260 is the same as the number of the holding grooves 222. The suction hole 260 is disposed at a circumferential position identical to that of the corresponding holding groove 222. Each of the suction holes 260 is connected to a vacuum pump 255. While FIG. 23 illustrates the suction hole 260 in an exaggerated manner, a diameter of the suction hole 260 at a portion provided in the second disk 232 gradually decreases toward the third disk 233 in the axial direction.

As illustrated in FIGS. 21 and 23, the feeding rotor 220 includes a first suction passage 261 and the second suction passage 262 each of which extends from the suction hole 260 to the radial outside of the feeding rotor 220. A position of the first suction passage 261 in the circumferential direction of the feeding rotor 220 is identical to a position of the second suction passage 262 in the circumferential direction of the feeding rotor 220. The first suction passage 261 is positioned on a first disk 231 side from the center of the feeding rotor 220 in the axial direction, and the second suction passage 262 is positioned on a third disk 233 side from the center of the feeding rotor 220 in the axial direction. The first suction passage 261 is opened so as to extend from the first holding face 222a to the second holding face 222b of the holding groove 222. Likewise, the second suction passage 262 is opened so as to extend from the first holding face 222a to the second holding face 222b of the holding groove 222. In the present embodiment, the opening of the first suction passage 261 is indicated as a “first suction port 261a”, and the opening of the second suction passage 262 is indicated as a “second suction port 262a”.

As illustrated in FIG. 22, a suction groove 232a extending in a radial direction of the second disk 232 is provided in a surface of the second disk 232 on the first disk 231 side. Then, a circumferential wall of the suction groove 232a and the first disk 231 form the first suction passage 261. In addition, a suction groove 232b extending in the radial direction of the second disk 232 is also provided in a surface of second disk 232 on the third disk 233 side. Then, a circumferential wall of the suction groove 232b and the third disk 233 form the second suction passage 262.

When the element body 271 is held in the holding groove 222, the first suction port 261a is closed by the first side face 271a and the second side face 271b of the first flange 281. Likewise, the second suction port 262a is closed by the first side face 271a and second side face 271b of the second flange 282. Thus, in the present embodiment, the feeding rotor 220 is configured to hold the element body 271 in the holding groove 222 while its first flange 281 and second flange 282 are suctioned.

In the present embodiment, two suction passages 261 and 262 can be provided in one holding groove 222 without providing a through-hole communicating with the suction hole 260 in any one of the disks 231 to 233. That is, in the present embodiment, the suction grooves 232a and 232b are formed in the second disk 232, and the second disk 232 is put in between the first disk 231 and the third disk 233 to enable two suction passages 261 and 262 to be provided in one holding groove 222. Thus, the suction passages 261 and 262 can be easily formed as compared with a case where a very thin through-hole is formed in a disk (e.g., the second disk 232).

Subsequently, an electrical configuration of the treatment apparatus will be described.

As illustrated in FIG. 24, the treatment apparatus 210 includes a control device 251 serving as a control system, a part feeder 211, a separating pin drive unit 252, a motor 240, a camera 253 serving as a photographing system, an illumination device 254, a laser device 213, a vacuum pump 255, and a charging pump 256.

The separating pin drive unit 252 is a solenoid, for example. The control device 251 controls the separating pin drive unit 252 so as to vertically move a separating pin 14b illustrated in FIG. 19.

The vacuum pump 255 is connected to a contact member 214a illustrated in FIG. 19 to be used to feed the element body 271. The vacuum pump 255 is also used to suction each of flanges 281 and 282 of the element body 271 through the first suction port 261a and the second suction port 262a illustrated in FIG. 21.

The charging pump 256 is used to supply compressed air to eject the element body 271.

The camera 253 and the illumination device 254 are used to grasp a position of the element body 271 held in the feeding rotor 220 to correct a treatment position of the laser device 213. The camera 253 and the illumination device 254 are also used to determine a side face to be treated in the element body 271. Correction of a treatment position and determination of a side face will be described below.

Subsequently, various treatment positions in the treatment apparatus 210 of the present embodiment will be described.

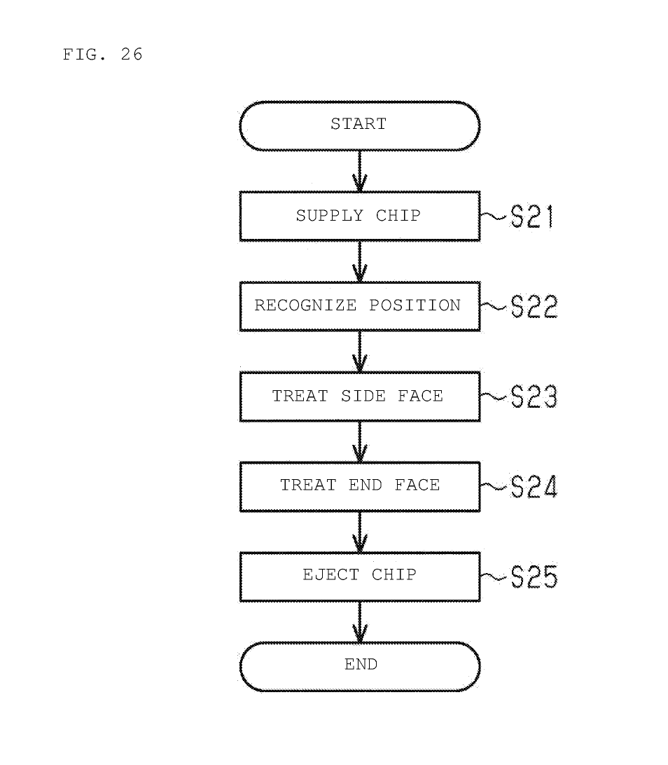

As illustrated in FIG. 25, the part feeder 211, the camera 253, the illumination device 254, and laser devices 213a, 213b, and 213c, are disposed around the feeding rotor 220.

Black circles each illustrated on the circumference of the feeding rotor 220 indicate a treatment position. The treatment position includes a delivery position P20, a recognition position (inspection position) P21, irradiation positions P22a, P22b, and P22c, and an ejection position P23. Each of the treatment positions is set in accordance with an angle at which the holding groove 222 illustrated in FIG. 18 is formed. In the present embodiment, the holding groove 222 is formed every three degrees. Thus, each of the treatment positions is set at an angle of an integral multiple of an angle at which the holding groove 222 is formed.

Specifically, the part feeder 211 is disposed below the feeding rotor 220. The element body 271 fed by the part feeder 211 is held in the holding groove 222 (refer to FIG. 18) of the feeding rotor 220 at the delivery position P20 positioned at the lowermost point of the feeding rotor 220.

In FIG. 25, the feeding rotor 220 is rotationally driven in a direction indicated by the arrow. The element body 271 being fed is photographed with the camera 253 at the recognition position P21. The camera 253 and the illumination device 254 each are disposed at a position corresponding to the recognition position P21. The illumination device 254 is a ring illumination device, for example. The camera 253 photographs the element body 271 and the feeding rotor 220 from an outer periphery side of the feeding rotor 220. The element body 271 is held in the feeding rotor 220 in a form as illustrated in FIGS. 20A and 20B. When the element body 271 is held in the holding groove 222, the element body 271 may be displaced in position in its axial direction (the vertical direction in FIG. 20B or a direction perpendicular to an end face). Thus, the camera 253 photographs the element body 271 and the feeding rotor 220 to grasp a position of the element body 271. Specifically, the control device 251 grasps a position of the element body 271 with respect to the feeding rotor 220. Then, the control device 251 corrects a treatment position of the laser device 213 that treats a surface of the element body 271, in accordance with the grasped position of the element body 271. In the present embodiment, the laser device 213 is a laser treatment device, and the control device 251 corrects an emission angle of a laser beam of the laser device 213. This correction enables a side face of each element body 271 to be accurately treated.

In FIG. 25, the first to third irradiation positions P22a to P22c are set along a rotation direction of the feeding rotor 220. The first irradiation position P22a is a treatment position of treating the fourth side face 271d of each of the flanges 281 and 282 of the element body 271. The second and third irradiation positions P22b and P22c each are a treatment position of sequentially treating the end face 271e of each of the flanges 281 and 282 of the element body 271.

The first laser device 213a treats the fourth side face 271d of each of the flanges 281 and 282 of the element body 271 fed to the first irradiation position P22a. The first laser device 213a configured to emit a laser beam is disposed such that an optical axis La of the laser beam is to be perpendicular to the fourth side face 271d of each of the flanges 281 and 282 of the element body 271 fed to the first irradiation position P22a.

The second laser device 213b treats the end face 271e of the first flange 281 of the element body 271 fed to the second irradiation position P22b. The second laser device 213b configured to emit a laser beam is disposed such that the laser beam is incident substantially perpendicular to the end face 271e of the first flange 281 of the element body 271 fed to the second irradiation position P22b. The third laser device 213c treats the end face 271e of the second flange 282 of the element body 271 fed to the third irradiation position P22c. The third laser device 213c configured to emit a laser beam is disposed such that the laser beam is incident substantially perpendicular to the end face 271e of the second flange 282 of the element body 271 fed to the third irradiation position P22c. The second and third laser devices 213b and 213c each may be disposed such that a laser beam is incident substantially perpendicular to the end face 271e of each of the flanges 281 and 282 of the element body 271 by using one or more mirrors. Likewise, the first laser device 213a may be disposed such that its optical axis is to be perpendicular to the fourth side face 271 of each of the flanges 281 and 282 of the element body 271 by using one or more mirrors. The second and third laser devices 213b and 213c illustrated in FIG. 25 do not show their shapes, but show that they correspond to the irradiation positions P22b and P22c, respectively.

The element body 271 whose side faces and end faces are treated as described above is ejected at the ejection position P23 illustrated in FIG. 25.

Subsequently, a flow of treatment in a treatment apparatus will be described.

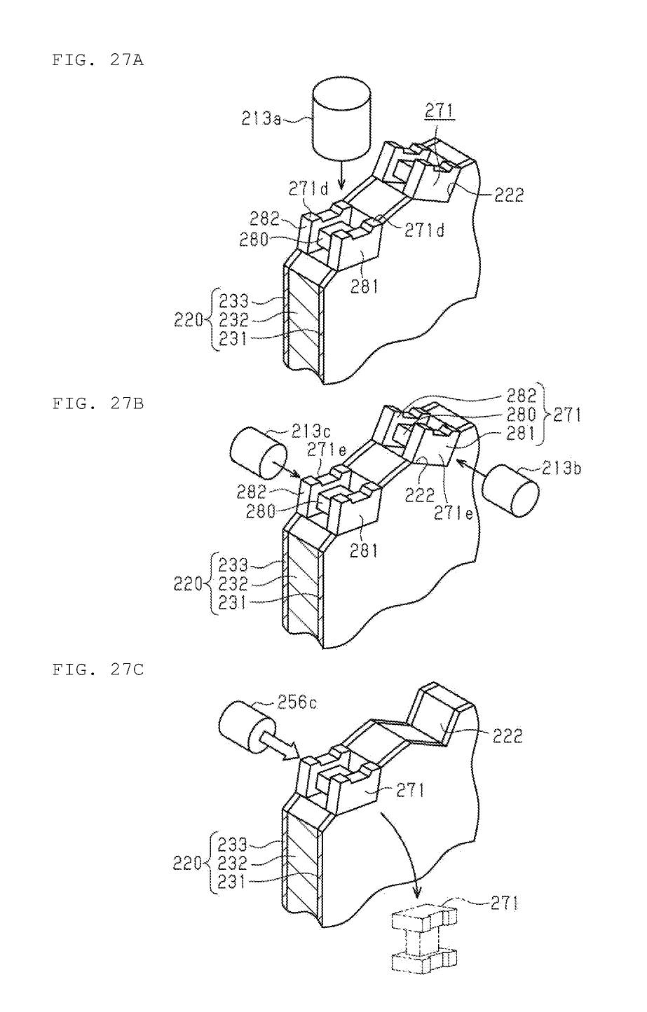

FIG. 26 illustrates a flow of treatment caused by the control device 251 of the treatment apparatus 210.

The control device 251 causes treatment of each of steps S21 to S25 illustrated in FIG. 26 to be performed, so that the element body 271 to be treated (refer to FIG. 17A) is treated.

In step S21, the element body 271 is supplied to the feeding rotor 220 illustrated in FIG. 18. Then, the feeding rotor 220 suctioning the element body 271 is rotated to feed the element body 271.

In step S22, a position of the element body 271 is recognized by using the camera 253 illustrated in FIG. 25.

In step S23, the fourth side face 271d of each of the flanges 281 and 282 of the element body 271 is treated. That is, a part of the fourth side face 271d of each of the flanges 281 and 282 is treated by using the first laser device 213a illustrated in FIG. 25. A laser beam sweeps on the fourth side face 271d of each of the flanges 281 and 282 to treat a predetermined region. For example, a laser beam with a spot diameter of 40 μm sweeps back and forth. At this time, a position of a laser beam with which the fourth side face 271d of each of the flanges 281 and 282 is irradiated is corrected on the basis of the position of the element body 271 recognized in step S22. This correction enables an irradiation position of a laser beam to be accurately set for each element body 271.

In step S24, the end face 271e of each of the flanges 281 and 282 of the element body 271 is treated. That is, a part of the end face 271e of each of the flanges 281 and 282 of the element body 271 is treated by using the second laser device 213b and the third laser device 213c, illustrated in FIG. 25. In step S25, the element body 271 is ejected.

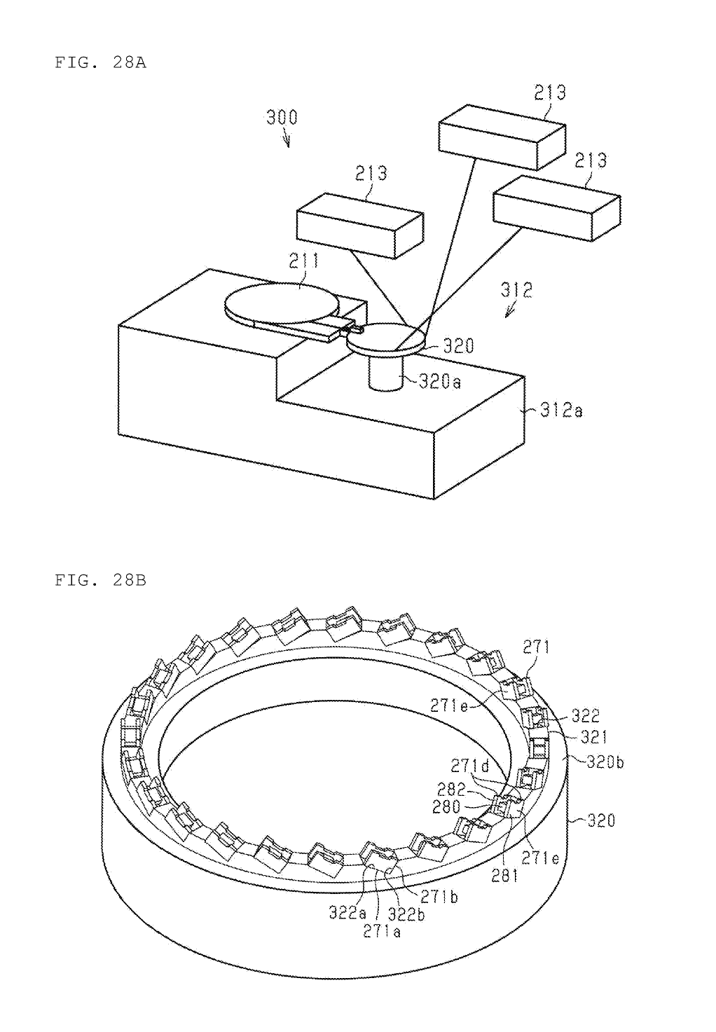

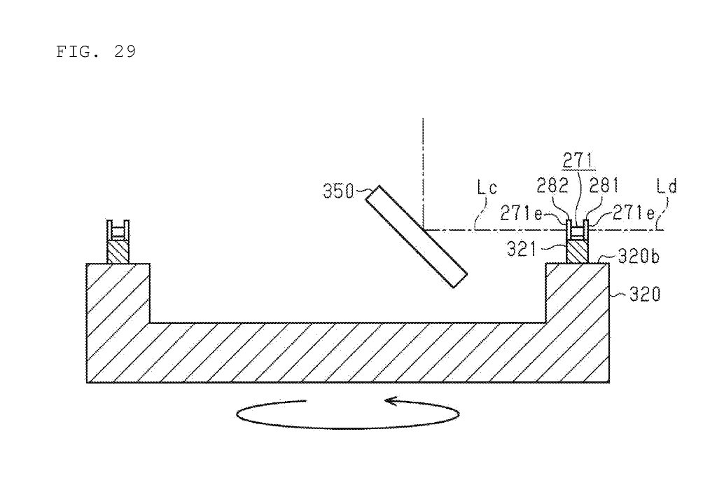

FIGS. 27A, 27B, and 27C each illustrate treatment of the element body 271.

First, the fourth side face 271d of each of the flanges 281 and 282 of the element body 271 is treated by using the first laser device 213a, as illustrated in FIG. 27A. Next, the end face 271e of the first flange 281 of the element body 271 is treated by using the third laser device 213c, as illustrated in FIG. 27B, and the end face 271e of the second flange 282 of the element body 271 is treated by using the third laser device 213c. Then, compressed air supplied from the charging pump 256 illustrated in FIG. 24 is injected through a nozzle 256c to eject the element body 271, as illustrated in FIG. 27C.

After treating the fourth side face 271d of each of the flanges 281 and 282 of the element body 271 as described above, the treatment apparatus 210 sequentially treats the two respective end faces 271e of the flanges 281 and 282. The laser device 213 irradiates a part of a surface of the element body 271 with a laser beam, so that irradiation energy of the laser beam causes the surface of the element body 271 to be locally heated. Irradiation with the laser beam may cause the element body 271 to be displaced in position. Likewise, irradiation of the end face 271e of each of the flanges 281 and 282 with a laser beam may cause this positional displacement. Thus, it is conceivable that a position of the element body 271 is recognized just before each treatment.

Displacement in position of the element body 271 causes deterioration in accuracy of treatment of a fourth side face 271d of each of flanges 281 and 282. Thus, after a process of recognizing a position of the element body 271 (step S22 of FIG. 26) is performed, an irradiation position is corrected in accordance with the position of the element body 271 to treat its side face (step S23 of FIG. 26), thereby preventing deterioration in accuracy of the treatment.

Meanwhile, a side face of each of flanges 281 and 282 of the element body 271 is held in the feeding rotor 220. Thus, positional displacement of the element body 271 is caused in an axial direction of the element body 271. Even if the positional displacement is caused as described above, positional displacement of the element body 271 in a direction orthogonal to the axial direction of the element body 271 out of directions along the end face 271e with respect to the feeding rotor 220, is not caused. That is, positional displacement thereof is not caused at the second irradiation position P22b and the third irradiation position P22c, illustrated in FIG. 25. As a result, after a side face of the element body 271 is treated (step S23 of FIG. 26), an end face thereof can be treated (step S24 of FIG. 26) without recognizing a position of the element body 271.

Subsequently, operation of the treatment apparatus 210 described above will be described.

The treatment apparatus 210 includes a feeding device 212 and a laser device 213. The feeding device 212 includes the feeding rotor 220 and the motor 240. The feeding rotor 220 is rotatably supported, and is formed in a circular shape. In a radially outward edge portion of the feeding rotor 220, the holding grooves 222 are formed at equal angular intervals. The laser device 13 treats a surface of the element body 271 fed to a treatment position. The control device 251 controls the motor 240 so as to stop the feeding rotor 220 at every predetermined angle (an angle at which the holding groove 222 is formed) and so as to feed the element body 271 to a treatment position. Then, the control device 251 controls the laser device 213 so as to treat a surface of the element body 271.

According to this structure, chips are fed by the circular feeding rotor 220 so that each of their element bodies 271 is treated at a predetermined treatment position. As a result, treatment can be efficiently performed, or capacity in the treatment can be improved, as compared with a case where chips disposed on a table are treated, for example. In addition, the feeding rotor 220 is rotationally driven to feed element bodies 271, so that the plurality of element bodies 271 can be treated without changing position of the laser device 213, thereby enabling improvement in treatment capacity.

In the treatment apparatus 210, the control device 251 stops the feeding rotor 220 at every angle at which the holding groove 222 is formed, and causes a surface of the element body 271 stopped at a treatment position to be treated. As described above, the feeding rotor 220 is stopped at every angle at which the holding groove 222 is formed, so that the element body 271 can be reliably stopped at a treatment position. Then, the element body 271 stopped at the treatment position can be accurately treated.

The element body 271 is a ceramic element, and the laser device 213 is a laser treatment device that locally heats a surface of the ceramic element to reduce resistance in a part of the ceramic element. Thus, the element body 271 being a ceramic element is irradiated with a laser beam, so that a surface of the minute element body 271 can be locally and accurately heated. When the ceramic element is locally heated as described above to reduce resistance in its local portion, an external electrode can be formed by applying plating to the local portion.

Each of the holding grooves 222 of the feeding rotor 220 is formed such that all of two side faces adjacent to each other of each of the flanges 281 and 282 of the element body 271 are brought into surface contact with the holding groove 222. The laser device 213 includes the first laser device 213a corresponding to a fourth side face 271d of side faces 271a to 271d of each of flanges 281 and 282, the fourth side face 271d being not held, and the second laser device 213b and the third laser device 213c, corresponding to end faces 271e of the flanges 281 and 282, respectively.

Two suction ports 261a and 262a are provided in one holding groove 222 so as to extend from the first holding face 222a to the second holding face 222b of the holding groove 222.

Then, the flanges 281 and 282 of the element body 271 are suctioned onto the holding faces 222a and 222b through the two suction ports 261a and 262a, respectively, by using vacuum. This enables the element body 271 to be rotatably held in the feeding rotor 220.

As illustrated in FIG. 23, a connection portion of the second suction passage 262 to the suction hole 260 is closer to the vacuum pump 255 than a connection portion of the first suction passage 261 to the suction hole 260. Thus, a cross-sectional area of a passage of the connection portion of the first suction passage 261 to the suction hole 260 is more than a cross-sectional area of a passage of the connection portion of the second suction passage 262 thereto. This enables reduction in a variation between force of suction of the first flange 281 of the element body 271 and force of suction of the second flange 282 thereof.

In the element body 271 held in the feeding rotor 220, its fourth side face 271d and end face 271e of each of the flanges 281 and 282 can be treated.

The control device 251 controls the first laser device 213a, the second laser device 213b, and the third laser device 213c, so as to treat the fourth side face 271d and the end face 271e of each of the flanges 281 and 282 of the element body 271. Specifically, the control device 251 controls the first laser device 213a on the basis of a photographed result of the camera 253 so as to treat the fourth side face 271d of each of the flanges 281 and 282 of the element body 271. After that, the control device 251 controls the second laser device 213b so as to treat the end face 271e of the first flange 281 of the element body 271, and subsequently controls the third laser device 213c so as to treat the end face 271e of the second flange 282 of the element body 271.

Along a rotation direction of the feeding rotor 220, a treatment position, at which the corresponding one of the first to third laser devices 213a to 213c treats the element body 271, is set. The element body 271 is held in the holding groove 222. When a surface of the element body 271 is treated, the element body 271 may be displaced in position. Positional displacement of the element body 271 is caused in the axial direction of the element body 271 held in the holding groove 222. However, the end face 271e of each of the flanges 281 and 282 of the element body 271 is not displaced in position in a direction along the end face 271e. Thus, treating the end face 271e after the fourth side face 271d are treated enables the respective faces to be accurately treated.

As described above, the present embodiment achieves effects described below.

(3-1) The treatment apparatus 210 includes a feeding device 212 and a laser device 213. The feeding device 212 includes the feeding rotor 220 and the motor 240. The feeding rotor 220 is rotatably supported, and is formed in a circular shape. In a radially outward edge portion of the feeding rotor 220, the holding grooves 222 are formed at equal angular intervals. The laser device 213 treats a surface of each of the flanges 281 and 282 of the element body 271 fed to a treatment position. The control device 251 controls the motor 240 so as to stop the feeding rotor 220 at every predetermined angle (an angle at which the holding groove 222 is formed) and so as to feed the element body 271 to a treatment position. Then, the control device 251 controls the laser device 213 so as to treat a surface of each of the flanges 281 and 282 of the element body 271.

According to this structure, chips are fed by the circular feeding rotor 220 so that each of their element bodies 271 is treated at a predetermined treatment position. As a result, treatment can be efficiently performed, or capacity in the treatment can be improved, as compared with a case where chips disposed on a table are treated, for example. In addition, the feeding rotor 220 is rotationally driven to feed element bodies 271, so that the plurality of element bodies 271 can be treated without changing position of the laser device 213, thereby enabling improvement in treatment capacity.

(3-2) In the treatment apparatus 210, the control device 251 stops the feeding rotor 220 at every angle at which the holding groove 222 is formed, and causes a surface of each of the flanges 281 and 282 of the element body 271 stopped at a treatment position to be treated. As described above, the feeding rotor 220 is stopped at every angle at which the holding groove 222 is formed, so that the element body 271 can be reliably stopped at a treatment position. Then, the element body 271 stopped at the treatment position can be accurately treated.

(3-3) The element body 271 is a ceramic element, and the laser device 213 is a laser treatment device that locally heats a surface of the ceramic element to reduce resistance in a part of the ceramic element. Thus, the element body 271 being a ceramic element is irradiated with a laser beam, so that a surface of the minute element body 271 can be locally and accurately heated. When the ceramic element is locally heated as described above to reduce resistance in its local portion, an external electrode can be formed by applying plating to the local portion.

(3-4) The holding groove 222 includes the first holding face 222a that is brought into surface contact with the first side face 271a of each of the flanges 281 and 282 on the element body 271, and the second holding face 222b that is brought into surface contact with the second side face 271b of each of the flanges 281 and 282. According to this structure, the first side face 271a of each of the flanges 281 and 282 is brought into contact with the first holding face 222a of the holding groove 222, and the second side face 222b of each of the flanges 281 and 282 is brought into contact with the second holding face 222b of the holding groove 222, so that the feeding rotor 220 can stably hold the element body 271 in the holding groove 222. Then, in each of the flanges 281 and 282 of the element body 271 held in the holding groove 222, it is possible to treat the fourth side face 271d that is in non-contact with the first holding face 222a and the second holding face 222b of the holding groove 222, and the end face 271e by using the laser device 213.

(3-5) The feeding device 212 is configured to suction each of the flanges 281 and 282 of the element body 271 held in the holding groove 222. Thus, when each of the flanges 281 and 282 of the element body 271 is suctioned onto the first holding face 222a and second holding face 222b, the element body 271 can be held in the holding groove 222. That is, unlike the case where the shank 280 is suctioned, each of the suction ports 261a and 262a can be closed by the flanges 281 and 282, respectively. This enables the element body 271 to be properly held in the holding groove 222.

(3-6) Each of the first holding face 222a and the second holding face 222b that hold each of the flanges 281 and 282 is a plane and is not provided with a protrusion. This enables the part feeder 211 to come close to the feeding rotor 220. Thus, it is possible to reduce a time required to deliver the element body 271 to the feeding rotor 220 from the part feeder 211.

(3-7) The holding groove 222 is formed in a shape suitable for a shape of each of the flanges 281 and 282 of the element body 271. Thus, each of the flanges 281 and 282 is brought into surface contact with the first holding face 222a and the second holding face 222b of the holding groove 222. As a result, the element body 271 can be easily held in holding groove 222.

(3-8) Each of the flanges 281 and 282 of the element body 271 is formed such that its first side face 271a is longer than its second side face 271b, and thus in the holding groove 222, its first holding face 222a is longer than its second holding face 222b. As a result, it is possible to increase a contact area between the first side face 271a of each of the flanges 281 and 282, and the first holding face 222a, as much as possible. This enables stability when the element body 271 is held in the holding groove 222 to be further improved.

(3-9) The control device 251 controls the first laser device 213a, the second laser device 213b, and the third laser device 213c, so as to treat a surface of each of the flanges 281 and 282 of the element body 271. When the fourth side face 271d in non-contact with the holding groove 222 is a face to be treated in the side faces 271a to 271d of each of the flanges 281 and 282, the first laser device 213a is controlled for treatment depending on a state (posture) of the element body 271 held in the holding groove 222, and thus the fourth side face 271d of each of the flanges 281 and 282 of the element body 271 being fed can be treated without being affected by a state of the element body 271.

(3-10) The control device 251 controls the first laser device 213a on the basis of a photographed result of the camera 253 so as to treat the fourth side face 271d of each of the flanges 281 and 282 of the element body 271. When the first laser device 213a is controlled for treatment by grasping the fourth side face 271d of each of the flanges 281 and 282, the fourth side face 271d of each of the flanges 281 and 282 of the element body 271 being fed can be treated without being affected by a state of the element body 271.

When the first laser device 213a treats the fourth side face 271d of each of the flanges 281 and 282 of the element body 271, the element body 271 may be displaced in position. This positional displacement is caused in a direction orthogonal to the end face 271e of each of the flanges 281 and 282. The amount of the positional displacement caused in the element body 271 is less than a focus range of a laser beam emitted from each of the second and third laser devices 213b and 213c used to treat the end face 271e. Thus, the end face 271e of each of the flanges 281 and 282 can be treated with high accuracy.

(3-11) The control device 251 grasps a position of the element body 271 on the basis of a photographed result of the camera 253, and corrects a position of treatment to be applied to the element body 271 by the laser device 213 on the basis of the grasped position of the element body 271.

When the element body 271 is fed to the feeding rotor 220 from the part feeder 211, the element body 271 may be displaced in position. For that, the camera 253 photographs the element body 271 held by the feeding rotor 220 to grasp a position of the element body 271, and a treatment position is corrected in accordance with the grasped position, thereby enabling treatment with high accuracy.

### Fourth Embodiment

A fourth embodiment will be described below.

In the present embodiment, the component the same as that of the third embodiment described above is designated by the same reference sign to eliminate a part or all of the description of the component.

As illustrated in FIG. 28A, a treatment apparatus 300 includes a part feeder 211, a feeding device 312, and a laser device 213. FIG. 28A illustrates three laser devices 213. A straight line connecting each of the laser devices 213 to the feeding device 312 indicates a relationship between each of the laser devices 213 and the feeding device 312, and does not indicate a treatment position by each of the laser devices 213.

The feeding device 312 includes a feeding rotor 320, and a rotating shaft 320a that supports the feeding rotor 320. In the present embodiment, the rotating shaft 320a is vertically supported in a body portion 312a of the feeding device 312. Thus, the feeding rotor 320 rotates in a horizontal direction (lateral direction).

As illustrated in FIG. 28B, an annular support portion 321 extending along a circumferential direction of the feeding rotor 320 is formed in a top face 320b of the feeding rotor 320 formed in a circular shape. The support portion 321 is provided with a plurality of holding grooves 322 that is disposed along its circumferential direction at equal intervals, and the element body 271 is held in each of the holding grooves 322. In FIG. 28B, the element body 271 is illustrated in an enlarged manner to easily understand a holding state of the element body 271, so that the number of element bodies 271 illustrated is less than the number of element bodies 271 being actually held.

The holding groove 322 is formed so as to extend along the radial direction of the feeding rotor 320. The holding groove 322 is formed in a V-shape as viewed from the radial direction of the feeding rotor 320 so as to hold the element body 271 to be fed at an angle.

At this time, the element body 271 is held such that its side face to be treated, or the fourth side face 271d of each of the flanges 281 and 282 is positioned on an upper face side of the feeding rotor 320. In other words, the above part feeder 211 aligns the element body 271 such that the fourth side face 271d is positioned on the upper face side of the feeding rotor 320.

The holding grooves 322 are formed in an edge portion of the feeding rotor 320 at equal intervals (at equal angular intervals). Two suction ports (not illustrated) are formed so as to extend from a first holding face 322a to a second holding face 322b of the holding groove 322. The first side face 271a of each of the flanges 281 and 282 of the element body 271 is brought into surface contact with the first holding face 322a, and the second side face 271b of each of the flanges 281 and 282 is brought into surface contact with the second holding face 322b. As with the third embodiment, the element body 271 is held in the holding groove 322 while being suctioned by a vacuum pump.

In addition, as with the third embodiment, all of the first side face 271a of the element body 271 is brought into surface contact with the first holding face 222a, and all of the second side face 271b of the element body 271 is brought into surface contact with the second holding face 222b. A length of the support portion 321 in its radial direction is equal to a length of the element body 271 in its axial direction.

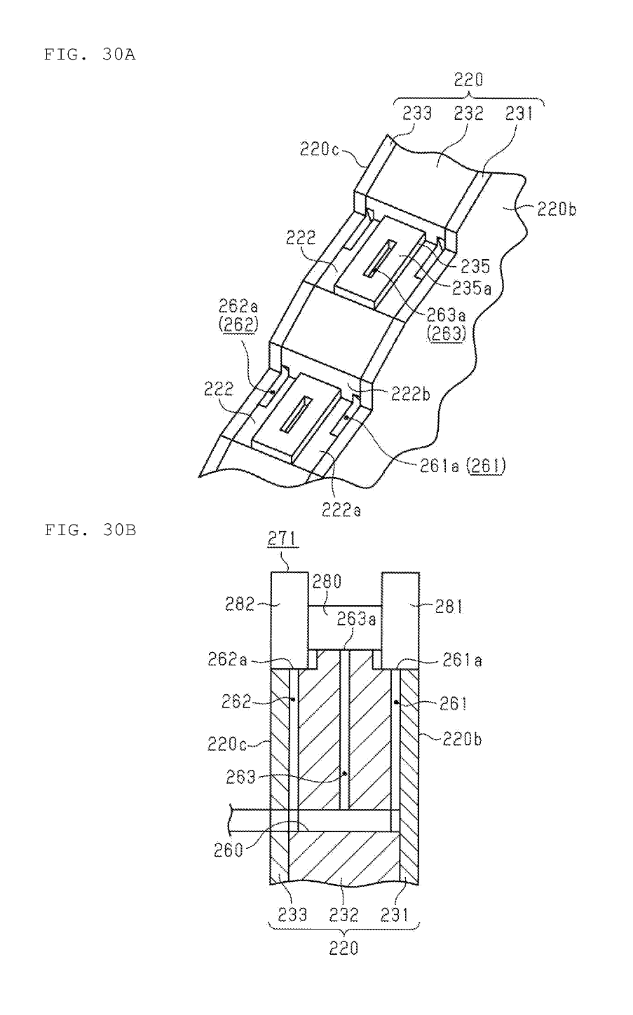

As illustrated in FIG. 29, the end face 271e of the second flange 282 of the element body 271 supported in the feeding rotor 320 is irradiated with a laser beam Lc (illustrated by a dashed line) by using a mirror 350 provided inward of the feeding rotor 320. In addition, the end face 271e of the first flange 281 of the element body 271 is directly irradiated with a laser beam Ld from outward of the feeding rotor 320.

As described above, the present embodiment achieves an effect described below in addition to the effects of the third embodiment.

(4-1) In the treatment apparatus 300 of the present embodiment, the feeding rotor 320 is supported to be able to horizontally rotate by having a rotating shaft 320a supported vertically, and is provided on its top face 320b with the annular support portion 321 extending along its circumferential direction. The holding groove 322 is provided on the top face of the support portion 321, and is formed so as to extend in the radial direction of the feeding rotor 320.

As described above, the feeding rotor 320 horizontally (laterally) rotates by using the rotating shaft 320a supported vertically. The element body 271 is held by the support portion 321 of the feeding rotor 320 that horizontally rotates as described above, so that the element body 271 can be fed in a stable state.

The third and fourth embodiments described above may be practiced by an aspect below.
In the third embodiment described above, the second disk 232 constituting the feeding rotor 220 may be provided with a protrusion 235 such as illustrated in FIGS. 30A and 30B. The protrusion 235 is configured to be positioned between the first flange 281 and the second flange 282 of the element body 271 held in the holding groove 222. Accordingly, when a direction in which the first flange 281, the shank 280, and the second flange 282 align, or an extending direction of the rotating shaft 220a, is indicated as an axial direction of the element body, the protrusion 235 can prevent the element body 271 held in the holding groove 222 from being displaced in the axial direction. That is, the element body 271 held in the holding groove 222 can be prevented from being displaced in position.

The protrusion 235 may have a shape having a leading end 235a that is brought into contact with a side face of the shank 280 of the element body 271. In this case, as illustrated in FIGS. 30A and 30B, the second disk 232 may be provided with a third suction passage 263 that extends in its radial direction and communicates with the suction hole 260. When the third suction passage 263 is opened in the leading end 235a of the protrusion 235, the protrusion 235 can be provided with a third suction port 263a that is used to suction the shank 280 of the element body 271 held in the holding groove 222. According to this structure, not only can each of the flanges 281 and 282 but also the shank 280 can be suctioned in the element body 271 held in the holding groove 222. This enables a holding position of the element body 271 held in the holding groove 222 to be more accurately prevented from being displaced.

While the protrusion 235 is provided in the first holding face 222a in an example illustrated in each of FIGS. 30A and 30B, the protrusion 235 may be provided in the second holding face 222b.

When the third suction passage 263 is provided in the feeding rotor 220 as described above, at least one of the first suction passage 261 and the second suction passage 262 may be eliminated if the element body 271 can be stably held in the holding groove 222 by force of suctioning the shank 280.
In the third and fourth embodiments, if the element body 271 can be stably held in the holding groove 222 by suctioning at least one of the first flange 281 and the second flange 282, any one of the first suction passage 261 and the second suction passage 262 may be eliminated.
In the third and fourth embodiments, while the treatment apparatuses 210 and 300 each are configured to treat the fourth side face 271d and the end face 271e of each of the flanges 281 and 282 of the element body 271, a face to be treated in the element body 271 to be treated is not limited to the faces of the embodiments described above. For example, only the fourth side face 271d of at least one of the flanges 281 and 282 may be treated. In addition, only the end face 271e of at least one of the flanges 281 and 282 may be treated. Further, the fourth side face 271d of each of the flanges 281 and 282, and only the end face 271e of at least one of the flanges, may be treated.
In the third and fourth embodiments, only one laser device 213a treats the element body 271 positioned at the first irradiation position P22a. However, a plurality of laser devices 213a (two or four) may be provided to treat the element body 271 positioned at the first irradiation position P22a.
In the third and fourth embodiments described above, while the treatment apparatuses 210 and 300 each include the laser device 213 that locally heats a surface of each of the flanges 281 and 282 of the element body 271 to form external electrodes 272 to 275 illustrated in FIGS. 16A and 16B, a system for performing another treatment may be fabricated. In addition, the treatment apparatuses 210 and 300 may be configured to treat the element body 271 by using a device other than a laser treatment device, as the laser device 213. For example, a device for applying liquid or resin by using a jet dispenser may be used.
In the third and fourth embodiments described above, any treatment other than treatment for irradiating a surface of each of the flanges 281 and 282 of the element body 271 with a laser beam from the laser device 213 may be applied to the element body 271 fed by each of the feeding rotors 220 and 320. For example, the treatment as described above includes a treatment for inspecting an appearance of the element body 271 having reached a treatment position, and a treatment for inspecting a performance of the element body 271 having reached the treatment position. In these cases, a device for performing each inspection corresponds to a treatment device.

Subsequently, there are additionally described technical ideas below that can be grasped from each of the embodiments described above and another embodiment.

(A) It is preferable that the control system controls the feeding system so as to stop the feeding rotor at every angle at which the holding groove is formed, and controls the treatment system so as to treat a surface constituting at least one of the first flange and the second flange of the element body stopped at the treatment position.

(B) It is preferable that the feeding rotor is supported to be able to vertically rotate by having a rotating shaft supported horizontally, and is provided on its outer peripheral surface with a support portion extending along its circumferential direction, and the holding groove is provided in an outer peripheral surface of the support portion, and is formed so as to extend along a direction parallel to the rotating shaft of the feeding rotor, and that the supply system is configured to feed the element body to the feeding system along an extending direction of the rotating shaft.

(C) It is preferable that the feeding rotor is supported to be able to horizontally rotate by having a rotating shaft supported vertically, and is provided on its top face with an annular support portion extending along its circumferential direction, and the holding groove is provided in a top face of the support portion, and is formed so as to extend along the radial direction of the feeding rotor, and that the supply system is configured to feed the element body to the feeding system along the radial direction of the feeding rotor.

(D) It is preferable that there is provided a photographing system that photographs the element body and the feeding rotor at a predetermined inspection position, and that the control system grasps a position of the element body on the basis of a photographed result of the photographing system, and corrects a position at which the treatment system treats the element body, in accordance with the grasped position of the element body.

(E) It is preferable that the electronic component includes the element body being a ceramic element, and an external electrode formed on a surface of at least one of the first flange and the second flange, and that the treatment system is a laser treatment device that locally heats a surface of the ceramic element to reduce resistance in a part of the ceramic element.

(F) It is preferable that the treatment device includes a first treatment device configured to treat the third side face of at least one of the first flange and the second flange, a second treatment device configured to treat the end face of the first flange, and a third treatment device configured to treat the end face of the second flange.

(G) It is preferable that the control system controls the first treatment device, and at least one of the second treatment device and the third treatment device, so as to treat a surface of at least one of the first flange and the second flange of the element body.

(H) It is preferable that the control system controls at least one of the first treatment device, the second treatment device, and the third treatment device, on the basis of a photographed result of a photographing system, so as to treat a surface corresponding to the controlled treatment device.

(I) It is preferable that treatment positions at which the corresponding first to third treatment systems treat the element body are set along a rotation direction of the feeding rotor.

What is claimed is:

1. A treatment apparatus that treats element bodies constituting electronic components, the treatment apparatus comprising:
a feeding system including a feeding rotor that is rotatably supported, and a drive unit rotationally driving the feeding rotor, wherein the feeding rotor has a plurality of holding grooves to hold the element bodies, and the plurality of holding grooves are disposed at equal angular intervals in an edge portion of the feeding rotor along a circumferential direction of the feeding rotor, and the feeding system feeds the element bodies held in the corresponding holding grooves;
a supply system supplying the element bodies to the corresponding holding grooves;
a treatment device treating each of the element bodies at a treatment position; and
a control system controlling the feeding system so as to feed each of the element bodies to the treatment position by rotationally driving the feeding rotor, and controlling the treatment device so as to treat each of the element bodies being fed.

2. The treatment apparatus according to claim 1, wherein
each of the holding grooves is formed so as to hold the element body when a part of two adjacent faces of the element body is in contact with the holding groove while allowing all two faces thereof parallel to the corresponding faces in contact with each of the holding grooves to project from a corresponding one of the holding grooves,
the element body has a rectangular parallelepiped shape and has two side faces which are each parallel to the corresponding one of the two faces in contact with each of the holding grooves, and has two end faces orthogonal to the two side faces and to the two faces in contact with each of the holding grooves, and
the control system controls the treatment device so as to treat at least one of one of the two side faces in non-contact with each of the holding grooves and the two end faces.

3. The treatment apparatus according to claim 2, wherein
the control system controls the feeding system so as to stop the feeding rotor at every angle at which each of the holding grooves is formed, and controls the treatment device so as to treat the element body stopped at the treatment position.

4. The treatment apparatus according to claim 2, wherein
the feeding rotor is supported to be able to vertically rotate by having a rotating shaft supported horizontally, and is provided on its outer peripheral surface with a support portion extending along its circumferential direction,
each of the holding grooves is provided in an outer peripheral surface of the support portion, and is formed so as to extend along a direction parallel to the rotating shaft of the feeding rotor, and
the support portion is formed such that both end faces of the element body held in each of the holding grooves project from the support portion in a direction parallel to the rotating shaft of the feeding rotor.

5. The treatment apparatus according to claim 2, wherein
the feeding rotor is supported to be able to horizontally rotate by having a rotating shaft supported vertically, and is provided on its top face with an annular support portion extending along a circumferential direction,
each of the holding grooves is provided in a top face of the support portion, and is formed so as to extend in a radial direction of the feeding rotor, and
the support portion is formed such that one of both end faces of the element body held in each of the holding grooves projects radially inward from the support portion, and the other of both the end faces projects radially outward from the support portion.

6. The treatment apparatus according to claim 1, further comprising:
a photographing system photographing the element body and the feeding rotor at a predetermined inspection position,
wherein the control system grasps a position of the element body on the basis of a photographed result of the photographing system, and corrects a position at which the treatment device treats the element body, in accordance with the grasped position of the element body.

7. The treatment apparatus according to claim 1, wherein
the electronic component includes the element body being a ceramic element, and an external electrode formed on a surface of the element body, and
the treatment device is a laser treatment device that locally heats a surface of the ceramic element to reduce resistance in a part of the ceramic element.

8. The treatment apparatus according to claim 2, wherein
the treatment device includes
a first treatment device configured to treat one of the two side faces,
a second treatment device configured to treat the other of the two side faces, and
a third treatment device and a fourth treatment device, configured to treat the corresponding two end faces.

9. The treatment apparatus according to claim 8, wherein
the control system controls one of either the first treatment device or the second treatment device, the third treatment device, and the fourth treatment device, so as to treat one side face and two end faces of the element body.

10. The treatment apparatus according to claim 8, wherein
the control system controls the first treatment device or the second treatment device on the basis of a photographed result of the photographing system so as to treat a side face corresponding to the controlled treatment device.

11. The treatment apparatus according to claim 8, wherein
treatment positions at which the corresponding first to fourth treatment devices treat the element body are set depending on a rotation direction of the feeding rotor.

12. The treatment apparatus according to claim 1, wherein
the element body includes a shank, a first flange connected to one end of the shank, and a second flange connected to the other end of the shank,
each of the flanges has a first side face, a second side face provided with one end connected to one end of the first side face, a third side face provided with one end connected to the other end of the first side face, a fourth side face connected to both of the other end of the second side face and the other end of the third side face, and an end face connected to all of the first side face, the second side face, the third side face, and the fourth side face,
the holding groove has a first holding face to be in contact with the first side face of each of the flanges, and a second holding face to be in contact with the second side face of each of the flanges, and
the control system controls the treatment device so as to treat a face which does not contact with the first holding face and the second holding face, in the faces constituting at least one of the two flanges.

13. The treatment apparatus according to claim 12, wherein
the feeding system is configured to suction at least one of the respective flanges of the element body held in each of the holding grooves.

14. The treatment apparatus according to claim 12, wherein
the feeding rotor has a protrusion protruding from the first holding face, the protrusion being positioned between the first flange and the second flange of the element body held in each of the holding grooves.

15. The treatment apparatus according to claim 13, wherein
the feeding rotor has a protrusion protruding from the first holding face, the protrusion being positioned between the first flange and the second flange of the element body held in each of the holding grooves, and
the protrusion includes a suction port through which the shank of the element body held in each of the holding grooves is suctioned.

16. The treatment apparatus according to claim 12, wherein
each of the holding grooves is formed in a shape suitable for each of the flanges of the element body held in each of the holding grooves.

17. The treatment apparatus according to claim 16, wherein
each of the flanges of the element body is formed such that the first side face is longer than the second side face, and
each of the holding grooves is formed such that the first holding face is longer than the second holding face.

18. A component feeder that feeds an element body constituting an electronic component,
the element body including a shank, a first flange connected to one end of the shank, and a second flange connected to the other end of the shank,
each of the flanges having a first side face, a second side face provided with one end connected to one end of the first side face, a third side face provided with one end connected to the other end of the first side face, a fourth side face connected to both of the other end of the second side face and the other end of the third side face, and an end face connected to all of the first side face, the second side face, the third side face, and the fourth side face,
the component feeder comprising:
a feeding system including a feeding rotor that is rotatably supported, and a drive unit rotationally driving the feeding rotor, wherein the feeding rotor has a plurality of holding grooves to hold the element bodies, and the plurality of holding grooves are disposed at equal angular intervals in an edge portion of the feeding rotor along a circumferential direction of the feeding rotor, and the feeding system feeds the element bodies held in each of the holding grooves; and
a supply system supplying the element bodies to each of the holding grooves,
each of the holding grooves having a first holding face to be in contact with the first side face of each of the flanges, and a second holding face to be in contact with the second side face of each of the flanges, and
the feeding system being configured to suction at least one of the respective flanges of the element bodies held in each of the holding grooves.

19. A treatment method used to treat an element body constituting an electronic component, the treatment method comprising the steps of:
holding the element body in each of a plurality of holding grooves that is disposed in an edge portion of a feeding rotor being rotatably supported, at equal angular intervals along a circumferential direction of the feeding rotor;
rotationally driving the feeding rotor to feed the element body to a treatment position set in a rotation direction of the feeding rotor; and
treating the element body at the treatment position.
